(19) United States
(12) Patent Application Publication
(10) Pub. No.: US 2005/0037282 A1
(43) Pub. Date: Feb. 17, 2005

(54) Lithographic printing plate precursor and lithographic printing method

(76) Inventor: Koji Sonokawa, Haibara-gun (JP)

Correspondence Address: BIRCH STEWART KOLASCH & BIRCH, PO BOX 747, FALLS CHURCH, VA, 22040-0747, US

(21) Appl. No.: 10/917,354

(22) Filed: Aug. 13, 2004

(30) Foreign Application Priority Data
Aug. 15, 2003 (JP) P. 2003-293814

(51) Int. Cl. G03F 7/00

(52) U.S. Cl. 430/270.1; 430/302

(57) ABSTRACT

A lithographic printing plate precursor comprising: a support; and an image recording layer containing (A) an infrared absorbing agent, (B) a polymerization initiator, (C) a polymerizable compound and (D) a compound having a carboxylate group and being removable with at least one of a printing ink and a fountain solution.

### FIELD OF THE INVENTION

This invention relates to a lithographic printing plate precursor and a lithographic printing method using the same. More specifically speaking, it relates to a lithographic printing plate precursor whereby a plate can be directly made by scanning with infrared lasers from digital signals of a computer or the like, i.e., so-called direct plate making, and a lithographic printing method wherein the above-described lithographic printing plate precursor is developed on a printer followed by printing.

### BACKGROUND OF THE INVENTION

In general, a lithographic printing plate consists of a lipophilic image part which receives an ink in the course of printing and a hydrophilic nonimage part which receives fountain solution. In lithographic printing, the lipophilic image part of a lithographic printing plate and the hydrophilic nonimage part thereof are employed respectively as an ink-receiving part and a fountain solution-receiving part (an ink-unrecieving part) by taking advantage of the imcompatibility between water and an oily ink. As a result, the ink unevenly adheres to the surface of the lithographic printing plate, i.e., the ink adheres exclusively to the mage part. Next, the ink is transferred onto a print substrate such as paper, thereby completing printing.

To construct such a lithographic printing plate, it has been a common practice to use a lithographic printing plate precursor (a PS plate) having a lipophilic photosensitive resin layer (an image recording layer) formed on a hydrophilic support. A lithographic printing plate is usually made by exposing a lithographic printing plate precursor via a master such as a lith film and dissolving and removing the image recording layer in the nonimage part with the use of an alkaline developing solution or an organic solvent while remaining the image recording layer in the image part to thereby expose the surface of the hydrophilic support.

In the plate making process with the use of a conventional lithographic printing plate precursor, it is necessary to employ the step of dissolving and removing the nonimage part with a developing solution or the like appropriate for the image recording layer after the exposure. It has been required to omit or simplify such an additional wet treatment. In recent years, the disposal of waste solutions discharged in association with the wet treatment has attracted much industrial attention from the viewpoint of global environment. Thus, it becomes more urgent to solve the above problem.

Under these circumstances, there has been proposed a so-called on board development method, as one of simplified plate making methods, which comprises using an image recording layer allowing the removal of a nonimage part of a lithographic printing plate precursor during the common printing process and, after exposing, removing the nonimage part on a printer to give a lithographic printing plate.

Specific examples of the onboard development method include a method with the use of a lithographic printing plate precursor having an image recording layer which can be dissolved or dispersed in a fountain solution, an ink solvent or am emulsion of a fountain solution with an ink; a method of mechanically removing an image recording layer by contacting it with an impression cylinder or a blanket cylinder of a printer; and a method wherein the cohesive force of an image recording layer or the adhesion between the image recording layer and a support is weakened by the penetration of a fountain solution, an ink solvent or the like and then the image recording layer is mechanical removed by contacting it with an impression cylinder or a blanket cylinder.

Unless otherwise noted, the term “development treatment” as used in the invention means the step of removing an unexposed part of the image recording layer of a lithographic printing plate precursor by using an apparatus (usually an automatic developing machine) other than a printer and contacting the image recording layer with a liquid (usually an alkaline developing solution) to thereby expose the surface of a hydrophilic support. On the other hand, the term “onboard development” means the method and step of removing an unexposed part of the image recording layer of a lithographic printing plate precursor by using a printer and contacting the image recording layer with a liquid (usually a printing ink and/or a fountain solution) to thereby expose the surface of a hydrophilic support.

With the recent spread of digitalization techniques of electronically processing, accumulating and outputting image data with a computer, various image output systems appropriate for these digitalization techniques have been put into practical use. Thus, there have been developed computer to plate techniques whereby a printing plate is directly exposed, without resort to a lith film, by scanning highly directional light such as laser beams on the printing plate in accordance with digitalized image data. Accordingly, it is one of important technical problems to obtain a photosensitive lithographic printing plate appropriate for these systems.

As discussed above, it has been more urgently required in these days than before to simplify the plate making procedures and employ dry and no-treating systems from the viewpoints of both of the protection of the global environment and the adaptation to the digitalization.

In the case of applying the conventional image recording system with the use of ultraviolet to visible rays to the simplified plate making procedures such as the onboard development, however, the image recording layer would not be fixed after the exposure and, therefore, sustains its photosensitivity to room light. Thus, such a lithographic printing plate precursor should be completely blocked from light after taking out from a package until the onboard development is completed.

In recent years, high output lasers such as semiconductor lasers and YAG lasers emitting infrared rays of 760 nm to 1200 nm in wavelength are available less expensively. Accordingly, it is highly expected that these high output lasers are useful as image recording light sources in a method of producing a lithographic printing plate precursor by scanning exposure which can be easily incorporated into the digitalization technology.

In the conventional plate making method with the use of rays within the ultraviolet to visible ranges, a photosensitive lithographic printing plate precursor is exposed in an image pattern at a low to medium illumination intensity. In the method with the use of the high-output lasers as described above, in contrast thereto, an area to be exposed is radiated with much light energy within an extremely short time. Thus, the light energy is efficiently converted into heat energy, thereby inducing a heat change such as a chemical change, a phase change or a morphological or structural change in the image recording layer. Using this change, an image is recorded. That is to say, the image data is input by the light energy such as laser beams, while image recording is carried by using out not only the light energy but also the reaction by heat energy. Such a recording system with the use of the heat generated by high power density exposure is called “heat mode recording” and the conversion of light energy into heat energy is called “photothermal conversion”.

Large merits of the plate making method with the use of the heat mode recording reside in that the image recording layer would not become light-struck at an ordinary illumination level such as room light, and that fixation of an image recorded by high illumination exposure is not essentially required. That is, a lithographic printing plate precursor to be used in heat mode recording is free from any fear of light-struck due to room light before the exposure and the fixation of an image is not essentially required after the exposure. When a plate making process, wherein an image recording layer insolubilized or solubilized by the exposure using high output lasers is employed and the exposed image recording layer in an image pattern is employed as a lithographic printing plate, is carried out by the onboard development method, for example, it is expected that a printing system in which an image is not affected even though it is exposed to environmental room light after the exposure could be obtained. Realization of such a system has been required.

As a lithographic printing plate precursor of the above-described type, a lithographic printing plate precursor having an image forming layer, in which hydrophobic thermoplastic polymer particles are dispersed in a hydrophilic binder, provided on a hydrophilic support is known (see, for example, Japanese Patent No. 2938397). This lithographic printing plate precursor is exposed by infrared laser beams and thus the hydrophobic thermoplastic polymer particles are thermally bonded together to form an image. Then it is loaded on a cylinder of a printer and a fountain solution and/or an ink are supplied to it. Thus, onboard development can be carried out.

Although this system wherein an image is formed by bonding fine particles merely via heat fusion shows favorable onboard development properties, the obtained image is very poor in strength and thus no sufficient printing tolerance can be established.

It is also known that a lithographic printing plate precursor having an image recording layer which contains microcapsules having a polymerizable compound encapsulated therein is usable in onboard development (see, JP-A-2001-277740 and JP-A-2001-277742).

Moreover, a lithographic printing plate precursor usable in onboard development which has a photosensitive layer containing an infrared absorbing agent, a radical polymerization initiator and a polymerizable compound on a support is known (see JP-A-2002-287334).

By the above-described methods using polymerization, the image strength can be elevated since chemical bond density in an image part is higher than that of an image formed by the heat fusion of fine polymer particles. However, the onboard development properties still remain insufficient.

On the other hand, a lithographic printing plate precursor in which a polycarboxylic acid compound is added as a sensitization aid to the image recording layer for alkali development is also known. (see International Patent Publication No. 048836/00). Moreover, it is known that a lithographic printing plate precursor having an image recording layer which contains a photopolymerizable radical undergoing polymerization when exposed to ultraviolet rays and a compound capable of forming a hydrogen bond as a hydrophilic group is usable in onboard development (see International Patent Publication No. 12759/97).

### SUMMARY OF THE INVENTION

An object of the invention is to overcome the above-described troubles occurring in the related art. That is to say, the invention aims at providing a lithographic printing plate precursor which is usable in image recording by infrared laser scanning, has improved onboard development properties and is excellent in storage stability, and a lithographic printing method.

As the results of intensive studies, the inventors have successfully achieved the above object by adding a compound having a specific carboxylate group to an image recording layer.

Accordingly, the present invention is as follows.

(1) A lithographic printing plate precursor having, on a support, an image recording layer containing (A) an infrared absorbing agent, (B) a polymerization initiator, (C) a polymerizable compound and (D) a compound having carboxylate group and being removable with a printing ink and/or a fountain solution.

(2) A lithographic printing plate precursor as described above characterized in that the compound having carboxylate group (D) is a monocarboxylic acid compound represented by the following formula (I):

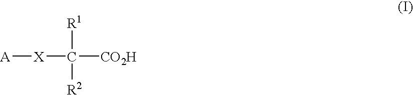

In the formula (I), A represents an aromatic group or a heterocyclic group.

R¹ and R² independently represent each a hydrogen atom or a monovalent substituent, or R¹ and R², one of R¹ and R² and X, one of R¹ and R² and A, or A and X may be bonded to each other to form a cyclic structure.

X represents a divalent linking group selected from among —O—, —S—, —SO₂—, —NH—, —N(R³)—, —CH₂—, —CH(R⁴)— and —C(R⁴)(R⁵)—, wherein R³, R⁴ and R⁵ independently represent each a hydrogen atom or a monovalent substituent.

It is preferable in the invention that X in the above formula (I) is a divalent linking group selected from among —NH—, —N(R³)—, —CH₂—, —CH(R⁴)— and —C(R⁴)(R⁵)—, still preferably —NH— or —N(R³)—, and most desirably —N(R³)—.

It is preferable that the substituent represented by R³ has at least one of —CO₂— and —CON(R⁸)— in its structure. The most desirable structures of R³ are represented by the following formulae. In the following formulae, R⁶, R⁷ and R⁸ independently represent each a hydrogen atom or a monovalent substituent, while Z represents a monovalent substituent.

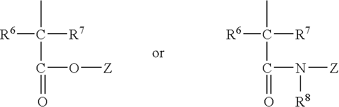

(3) A lithographic printing plate precursor as described in the above (1) or (2) characterized in that the polymerization initiator (B) is an onium salt represented by one of the following formulae (B-I) to (B-III):

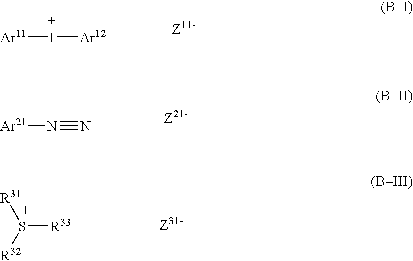

In the formula (B-I), Ar¹¹ and Ar¹² independently represent each an optionally substituted aryl group having not more than 20 carbon atoms. Z¹¹⁻ represents a counter ion selected from the group consisting of halogen ions, perchlorate ion, tetrafluoroborate ion, hexafluorophosphate ion, carboxylate ion and sulfonate ion.

In the formula (B-II), Ar²¹ represents an optionally substituted aryl group having not more than 20 carbon atoms. Z²¹⁻ represents a counter ion having the same meaning as Z¹¹.

In the formula (B-III), R³¹, R³² and R³³ may be the same or different and each represents an optionally substituted hydrocarbon group having not more than 20 carbon atoms. Z³¹⁻ represents a counter ion having the same meaning as Z¹¹.

(4) A lithographic printing plate precursor having an image recording layer containing (A) an infrared absorbing agent, (B) a polymerization initiator, (C) a polymerizable compound and (D) a compound having carboxylate group and being removable with a printing ink and/or a fountain solution, wherein at least one of (A) to (D) has been microcapsulated.

(5) A lithographic printing method wherein printing is carried out by loading a lithographic printing plate precursor as described in any of the above (1) to (4) a printer followed by exposure to infrared laser beams in an image pattern, or exposing the lithographic printing plate precursor to infrared laser beams in an image pattern followed by loading on a printer, and supplying an oily ink and an aqueous component to the lithographic printing plate precursor to thereby remove an infrared-unexposed part of the image recording layer.

The conventional image-forming methods using polymerization are effective in elevating image strength and improving printing tolerance. In these methods, however, a fountain solution and/or an ink slowly penetrate into an unexposed part of the image recording layer and thus only insufficient onboard development can be obtained in many cases. In contrast, the invention makes it possible to establish both of favorable onboard development and high storage stability by adding a compound having carboxylate group to the image recording layer.

Although the function mechanism of the invention has not sufficiently clarified, it is estimated as follows. By adding the compound having carboxylate group to the image recording layer, the compound interacts with the infrared absorbing agent (A) and thus elevates the decomposition rate of the polymerization initiator (B). Since a radical generator is employed as the polymerizable compound (B) in the invention, the polymerization-initiating radicals and polymerization-developing radicals thus generated undergo radical chain transfer toward the compound having carboxylate group, thereby promoting the polymerization of the polymerizable compound (C). Namely, it appears that polymerization is promoted in the image recording layer containing the compound having carboxylate group and thus the sensitivity is elevated. On the other hand, an unexposed part can be easily removed owing to the carboxylic acid having a hydrophilic nature. As a result, the lithographic printing plate precursor with the use of the image recording layer according to the invention seemingly establishes favorable onboard development.

In general, addition of such a compound capable of interacting with an infrared absorbing agent or a radical initiator to elevate sensitivity as described above to a polymerizable composition brings about a problem of lowering the storage stability of the composition per se. However, the compound having carboxylate group according to the invention never causes such a problem. Moreover, it exerts an additional effect of elevating the storage stability of a radical-polymerizable sensitive material which inherently has an insufficient storage stability. This is seemingly because the compound having carboxylate group according to the invention forms a complex together with the radical initiator and thus thermally stabilizes the radical initiator during storage.

As discussed above, it is assumed that both of favorable onboard development and high storage stability can be thus achieved by the invention.

According to the invention, a lithographic printing plate precursor which is usable in image recording by infrared laser scanning, has improved onboard development properties and is excellent in storage stability, and a method of printing a lithographic plate can be provided.

### DETAILED DESCRIPTION OF THE INVENTION

Now, the invention will be described in greater detail.

The lithographic printing plate precursor according to the invention is characterized by having, on a support, an image recording layer containing (A) an infrared absorbing agent, (B) a polymerization initiator, (C) a polymerizable compound and (D) a compound having carboxylate group and being removable with a printing ink and/or a fountain solution.

The lithographic printing plate precursor according to the invention is further characterized by containing at least one of (A) to (D) which has been microcapsulated.

The lithographic printing plate precursor according to the invention may further contain (E) a binder polymer to improve the film properties, etc.

Next, the components of the image recording layer of lithographic printing plate precursor according to the invention, constituents in elements other than the image recording layer such as a support thereof and the lithographic printing method according to the invention will be described in greater detail.

[(A) Infrared Absorbing Agent]

To ensure efficient image formation with the use of a light source emitting infrared rays of 760 nm to 1200 nm in wavelength, the image recording layer according to the invention contains an infrared absorbing agent. The infrared absorbing agent has a function of converting infrared rays absorbed by it into heat. Owing to the heat thus generated, a polymerization initiator (a radical generator) as will be described hereinafter is thermally decomposed and emits radicals. The infrared absorbing agent to be used in the invention is a dye or a pigment having an absorption maximum at 700 to 1200 nm.

As the dye, use can be made of commercially available dyes and publicly known ones described in documents, for example, Senryo Binran (ed. by The Society of Synthetic Organic Chemistry, Japan, 1970), etc. Specific examples thereof include azo dyes, metal complex salt azo dyes, pyrazolone azo dyes, naphthoquinone dyes, anthraquinone dyes, phthalocyanine dyes, carbonium dyes, quinoneimine dyes, methine dyes, cyanine dyes, squarylium dyes, pyrilium salts, metal thiolate complexes, oxonol dyes, diimonium dyes, aminium dyes, croconium dyes and so on.

Examples of preferable dyes include cyanine dyes described in JP-A-58-125246, JP-A-59-84356, JP-A-60-78787, etc., methine dyes described in JP-A-58-173696, JP-A-58-181690, JP-A-58-194595, etc., naphthoquinone dyes described in JP-A-58-112793, JP-A-58-224793, JP-A-59-48187, JP-A-59-73996, JP-A-60-52940, JP-A-60-63744, etc., squaryliumdyes described in JP-A-58-112792, etc., cyanine dyes described in British Patent 434,875, and so on.

Further, it is appropriate to use a near infrared absorbing sensitizer described in U.S. Pat. No. 5,156,938. Furthermore, use can be preferably made of substituted arylbenzo (thio) pyrilium salts described in U.S. Pat. No. 3,881,924, trimethine thiapyrilium salts described in JP-A-57-142645 (U.S. Pat. No. 4,327,169), pyrilium compounds described in JP-A-58-181051, JP-A-58-220143, JP-A-59-41363, JP-A-59-84248, JP-A-59-84249, JP-A-59-146063 and JP-A-59-146061, cyanine colorants described in JP-A-59-216146, pentamethine thiopyrilium salts described in U.S. Pat. No. 4,283,475 and pyrilium compounds described in JP-B-5-13514 and JP-B-5-19702.

As preferable examples of the dye, it is also possible to cite near infrared absorbing dyes represented by formulae (I) and (II) in U.S. Pat. No. 4,756,993.

As another preferable example of the infrared absorbing agent according to the present invention, a specific indolenine cyanine colorant described in JP-A-2002-178057 can be cited.

Among these dyes, particularly preferable examples include cyanine colorants, squarylium dyes, nickel thiolate complexes and the indolenine cyanine colorant. The cyanine colorants and the indolenine cyanine colorant are still preferable. In particular, cyanine colorants represented by the following formula (A-I) are highly desirable.

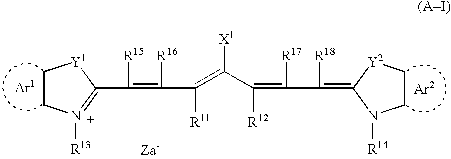

In the formula (A-I), X¹ represents a hydrogen atom, a halogen atom, —NPh₂, X²-L¹ or the following group.

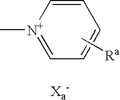

In the above formula, X² represents an oxygen atom, a nitrogen atom or a sulfur atom, while L¹ represents a hydrocarbon group having 1 to 12 carbon atoms, an aromatic ring having a hetero atom or a hydrocarbon group containing a hetero atom and having 1 to 12 carbon atoms. The term hetero atom as used herein means, N, S, O, a halogen atom or Se. Xa⁻ has the same meaning as will be defined with respect to Za⁻. R^{a} represents a substituent selected from among a hydrogen atom, an alkyl group, an aryl group, a substituted or unsubstituted amino group and a halogen atom.

R¹¹ and R¹² independently represent each a hydrocarbon group having 1 to 12 carbon atoms. Taking the storage stability of a coating solution for the recording layer into consideration, it is preferable that R¹¹ and R¹² are each a hydrocarbon group having 2 or more carbon atoms. It is still preferable that R¹¹ and R¹² are bonded to each other to form a 5-membered ring or a 6-memebred ring.

Ar¹ and Ar¹² may be either the same or different and each represents an optionally substituted aromatic hydrocarbon group. Preferable examples of the aromatic hydrocarbon group include a benzene ring and a naphthalene ring. Preferable examples of the substituent include hydrocarbon groups having 12 or less carbon atoms, halogen atoms and alkoxy groups having 12 or less carbon atoms. Y¹ and Y² may be either the same or different and each represents a sulfur atom or a dialkylmethylene group having 12 or less carbon atoms. R¹³ and R¹⁴ may be either the same or different and each represents an optionally substituted hydrocarbon group having 20 or less carbon atoms. Preferable examples of the substituent include alkoxy groups having 12 or less carbon atoms, a carboxyl group and a sulfo group. R¹⁵, R¹⁶, R¹⁷ and R¹⁸ may be either the same or different and each represents a hydrogen atom or a hydrocarbon group having 12 or less carbon atoms. From the viewpoint of the availability of starting materials, a hydrogen atom is favorable. Za⁻ represents a counter anion. However, Za⁻ is unnecessary in the case where the cyanine colorant represented by the formula (A-I) has an anionic substituent in its structure and thus the neutralization of the charge is unnecessary. From the viewpoint of the storage stability of a coating solution for the recording layer, preferable examples of Za⁻ include ahalogen ion, a perchlorate ion, a tetrafluoroborate ion, a hexafluorophosphate ion and a sulfonate ion. In particular, a perchlorate ion, a hexafluorophosphate ion and an arylsulfonate ion are preferable therefor.

Specific examples of the cyanine colorants represented by the formula (A-I) which are appropriately usable in the invention include those described in paragraphs [0017] to [0019] in JA-2001-133969.

As a still preferable example thereof, a specific indolenine cyanine colorant described in JP-A-2002-278057 may be cited.

As examples of the pigment to be used in the invention, commercially available pigments and pigments described in Color Index (C.I.) Binran, Saishin Ganryo Binran (ed. by Nippon Ganryo Gijutsu Kyokai, 1977), Saishin Ganryo Oyo Gijutsu (CMC Shuppan, 1986) and Insatsu Inki Gijutsu (CMC Shuppan, 1984) maybe cited.

Concerning the types of the pigments, use can be made of black pigments, yellow pigments, orange pigments, brown pigments, red pigments, purple pigments, blue pigments, green pigments, fluorescent pigments, metallic powder pigments, and polymer-binding pigments. More specifically speaking, use can be made of insoluble azo pigments, azo lake pigments, condensed azo pigments, chelate azo pigments, phthalocyanine-type pigments, anthraquinone-type pigments, perylene and perylene-type pigments, thioindigo-type pigments, quinacridone-type pigments, dioxazine-type pigments, isoindolinone-type pigments, quinophthalone-type pigments, underglaze lake pigments, azine pigments, nitroso pigments, nitro pigments, natural pigments, fluorescent pigments, inorganic pigments, carbon black and so on. Among these pigments, carbon black is preferred.

Such a pigment may be used without any surface treatment. Alternatively, it may be surface-treated before using. As the surface-treatment method, a method of coating the surface with a resin or a wax, a method of attaching a surfactant, a method of bonding a reactive substance (for example, a silane coupling agent, an epoxy compound, a polyisocyanate or the like) to the surface of the pigment, etc. may be suggested. These surface-treatment methods are reported by Kinzoku Sekken no Seishitu to Oyo (Saiwai Shobo), Insatsu Inki Gijutsu (CMC Shuppan, 1984) and Saishin Ganryo Oyo Gijutsu (CMC Shuppan, 1986).

The particle diameter of the pigment preferably ranges from 0.01 to 10 μm, still preferably from 0.05 to 1 μm and particularly preferably from 0.1 to 1 μm. So long as the particle diameter falls within this range, a high stability of the pigment dispersion in a coating solution of the image recording layer and a favorable uniformity of the image recording layer can be achieved.

To disperse the pigment, use can be made of a publicly known dispersion technique having been employed in producing inks, toners, etc. Examples of a dispersing machine include an ultrasonic disperser, a sand mill, an attritor, a pearl mill, a super mill, a ball mill, an impeller, a disperser, a KD mill, a colloidmill, a dynatron, a three-roll mill, a pressure kneader and so on. Details are described in Saishin Ganryo Oyo Gijutsu (CMC Shuppan, 1986).

Such an infrared absorbing agent may be added together with other components to a single layer. Alternatively, the infrared absorbing agent may be added to a layer which is separately formed. The infrared absorbing agent is added so that, in constructing a negative lithographic printing plate precursor, the image recording layer shows an absorbance of from 0.3 to 1.2 (measured by the reflection method), preferably from 0.4 to 1.1, at the maximum absorption wavelength within a wavelength range of from 760 nm to 1200 nm. So long as the absorbance falls within this range, polymerization uniformly proceeds in the depth direction of the image recording layer and thus a favorable film strength in an image part and an excellent adhesion to the support can be established.

The absorbance of the image recording layer can be controlled depending on the amount of the infrared absorbing agent to be added to the image recording layer and the thickness of the image recording layer. The absorbance can be measured by a common method. Examples of the measurement method include a method which comprises forming an image recording layer having a thickness, which is appropriately determined within a range required as a lithographic printing plate precursor by considering the coating dose after drying, on a reflective support (aluminum, etc.) and then measuring the reflection density with an optical densitometer, a method of measuring the reflection by the reflection method with the use of an integral sphere by using a spectrophotometer, etc.

Such an infrared absorbing agent is contained in the image recording layer in an amount of from 1 to 5% by mass based on the total solid matters in the image recording layer, preferably from 1 to 4% by mass based on the total solid matters and still preferably from 1 to 3% by mass based on the total solid matters. So long as the infrared absorbing agent content falls within this range, a favorable sensitivity can be obtained.

[(B) Polymerization Initiator]

The polymerization initiator usable in the invention generates radicals by heat or light energy or both thereof and thus initiates and promotes the hardening of the polymerizable compound as will be described hereinafter. Accordingly, a heat-decomposable radical generator which is decomposed by heat and generates radicals is useful as the polymerization initiator. By using such a radical generator together with the infrared absorbing agent as described above, the infrared absorbing agent generates heat upon irradiation with infrared laser beams and the heat induces the generation of radicals. That is to say, this combination enables heat mode recording.

As the radical generator, onium salts, triazine compounds trihalomethyl group, peroxides, azopolymerization initiators, azide compounds, quinone diazide compounds, etc. maybe cited. In particular, onium salts are preferred because of being highly sensitive. Next, onium salts appropriately usable as the radical polymerization initiator in the invention will be illustrated. Preferable examples of the onium salts include iodonium salts, diazonium salts and sulfonium salts. In the invention, such an onium salt serves not as an acid generator but a radical polymerization initiator. Onium salts represented by the following formulae (B-I) to (B-III) are particularly preferably employed in the invention.

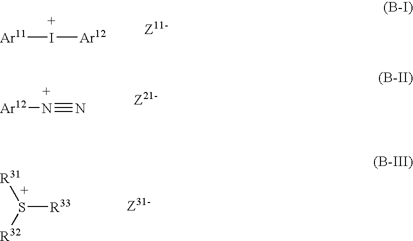

In the formula (B-I), Ar¹¹ and Ar¹² independently represent each an optionally substituted aryl group having not more than 20 carbon atoms. In the case where the aryl group has a substituent, preferable examples of the substituent include halogen atoms, a nitro group, alkyl groups having not more than 12 carbon atoms, alkoxy groups having not more than 12 carbon atoms and aryloxy groups having not more than 12 carbon atoms. Z^{11 -} represents a counter ion selected from the group consisting of halogen ions, a perchlorate ion, a tetrafluoroborate ion, a hexafluorophosphate ion, a carboxylate ion and sulfonate ions. It preferably represents a perchlorate ion, a hexafluorophosphate ion, a carboxylate ion or an arylsulfonate ion.

In the formula (B-II), Ar²¹ represents an optionally substituted aryl group having not more than 20 carbon atoms. Preferable examples of the substituent include halogen atoms, a nitro group, alkyl groups having not more than 12 carbon atoms, alkoxy groups having not more than 12 carbon atoms, aryloxy groups having not more than 12 carbon atoms, alkylamino groups having not more than 12 carbon atoms, dialkylamino groups having not more than 12 carbon atoms, arylamino groups having not more than 12 carbon atoms and diarylamino groups having not more than 12 carbon atoms. Z²¹⁻ represents the same counter ion as Z¹¹⁻.

In the formula (B-III), R³¹, R³² and R³³ may be the same or different and each represents an optionally substituted hydrocarbon group having not more than 20 carbon atoms. Examples of the substituent include halogen atoms, a nitro group, alkyl groups having not more than 12 carbon atoms, alkoxy groups having not more than 12 carbon atoms and aryloxy groups having not more than 12 carbon atoms. Z^{31 -} represents the same counter ion as Z^{31 -}.

Particular examples of the onium salt appropriately usable in the invention include the compounds described in JP-A-2001-133969, JP-A-2001-343742 and JP-A-2002-148790. Next specific examples of the onium salts represented by the formula (B-I) [(OI-1) to (OI-10)], specific examples of the onium salts represented by the formula (B-II) [(ON-1) to (ON-5)] and specific examples of the onium salts represented by the formula (B-III) [(OS-1) to (OS-10)] preferably usable in the invention will be presented, though the invention is not restricted thereto.

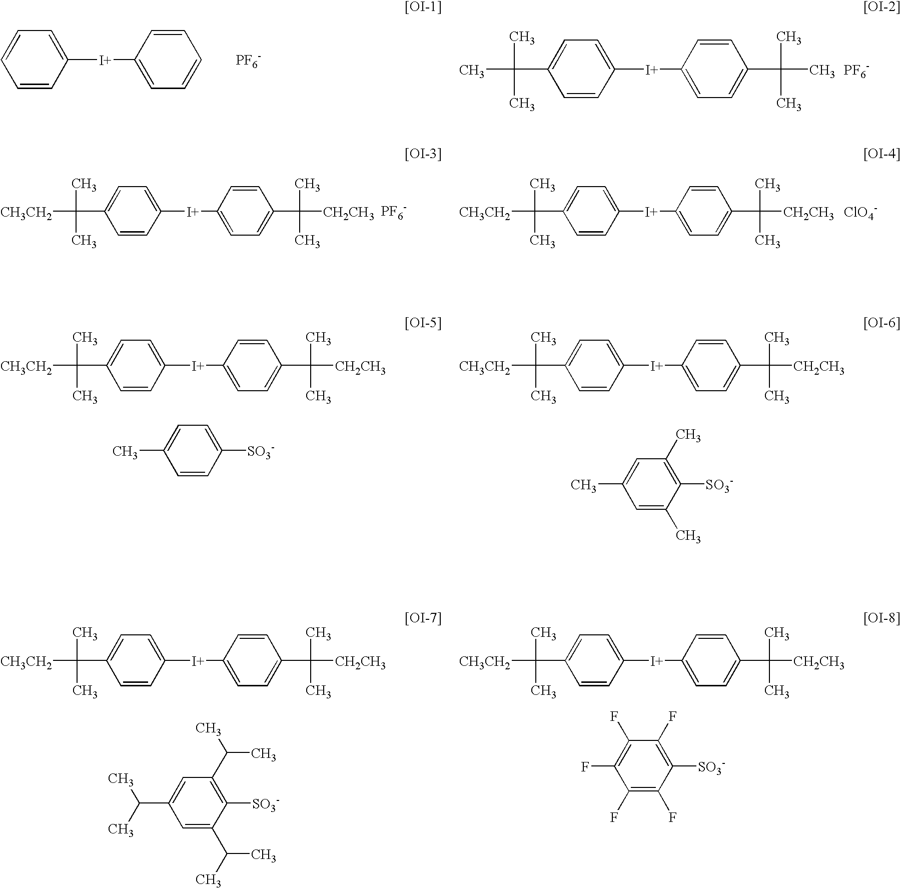

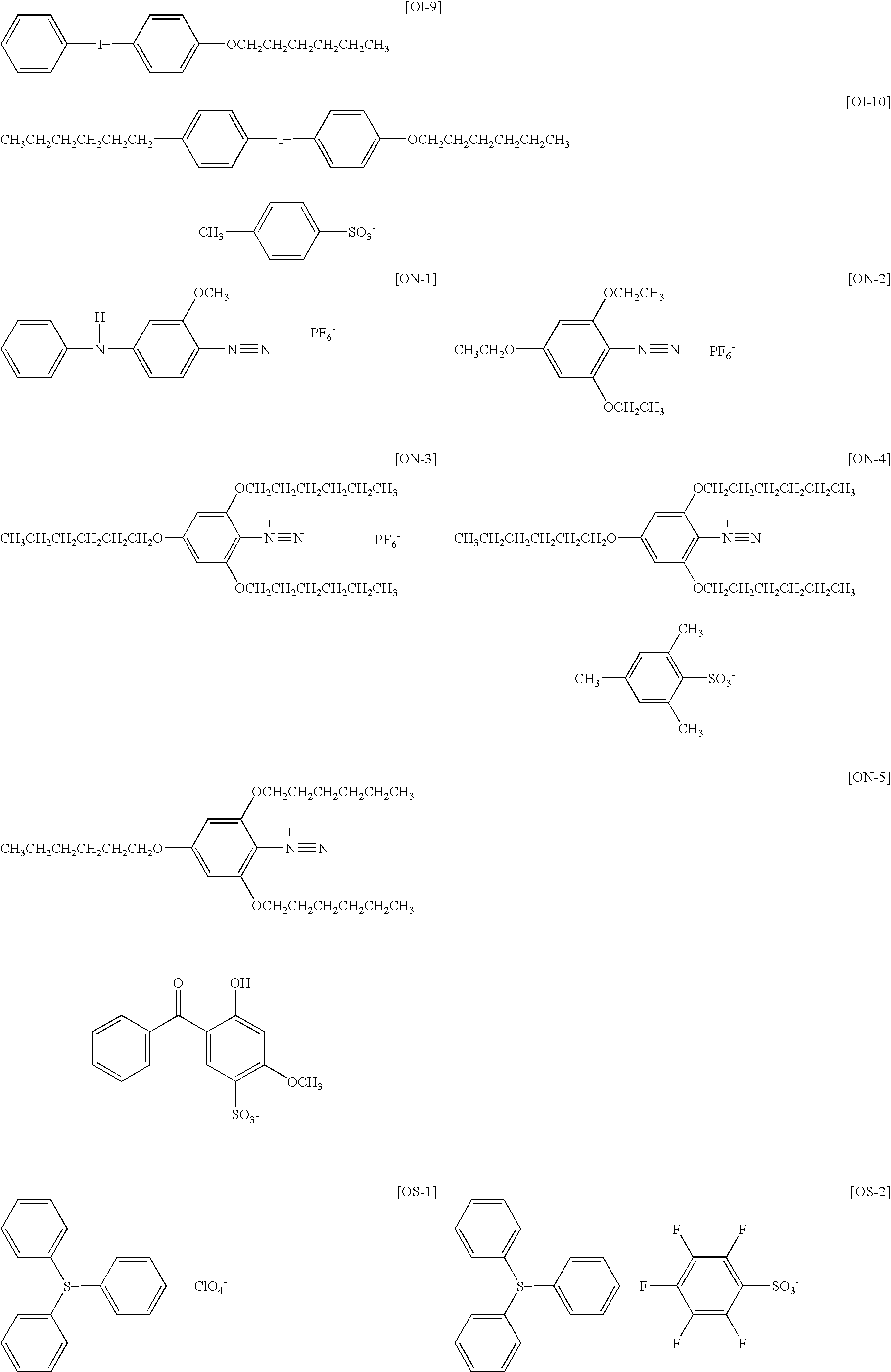

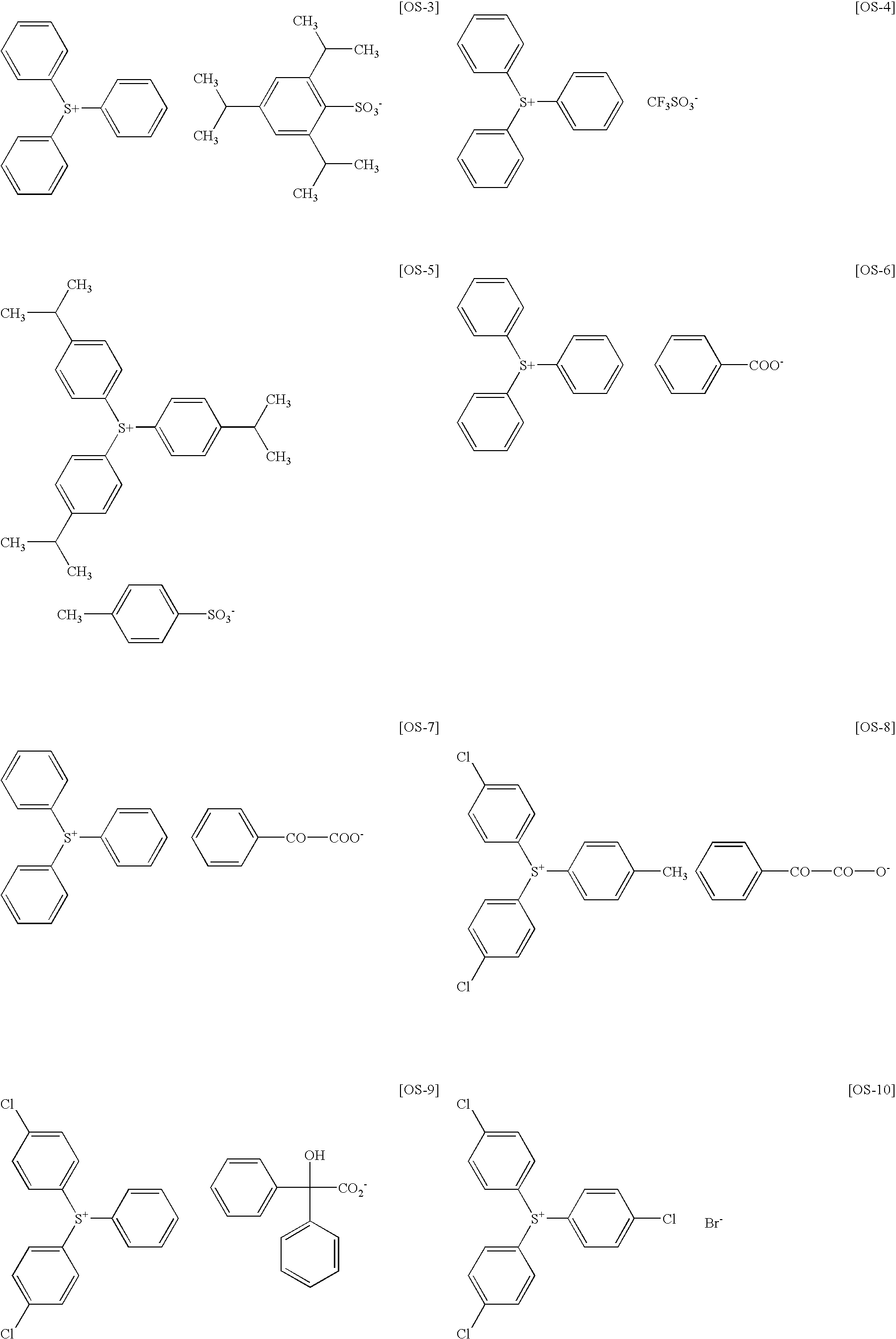

It is preferable that the radical generator to be used in the invention has a maximum absorption wavelength of 400 nm or less, still preferably 360 nm or less and most desirably 300 nm or less. By thus controlling the maximum absorption wavelength within the ultraviolet region, the lithographic printing plate precursor can be handled under white light.

Such a polymerization initiator may be added to the image recording layer in an amount of from 0.1 to 50% by mass based on the total solid matters constituting the image recording layer, preferably from 0.5 to 30% by mass and still preferably from 1 to 20% by mass. So long as the polymerization initiator content falls within this range, a favorable sensitivity and a favorable stain resistance in a nonimage part during printing can be obtained. Either one of these polymerization initiators or a mixture of two or more thereof may be used. The polymerization initiator may be added together with other components to a single layer. Alternatively, it may be added to another layer which is separately formed.

The polymerizable compound to be used in the invention is selected from the group consisting of addition-polymerizable compounds having at least one, preferably two or more terminal ethylenically unsaturated bond. Such compounds, which have been widely known in the art, can be employed in the invention without specific restriction. These compounds involve those having chemical forms of, for example, monomers, prepolymers (i.e., dimers, termers and oligomers), mixtures thereof and copolymers thereof. Examples of the monomers and copolymers thereof include unsaturated carboxylic acids (for example, acrylic acid, methacrylic acid, itaconic acid, crotonic acid, isocrotonic acid, maleic acid, etc.), esters thereof and amides thereof. It is preferable to use unsaturated esters of carboxylic acids with aliphatic polyhydric alcohols and amides of unsaturated carboxylic acids with aliphatic polyvalent amine compounds. Moreover, use may be appropriately made of addition reaction products of unsaturated carboxylic acid esters or amides having a nucleophilic substituent such as a hydroxyl group, an amino group or a mercapto group with monofunctional or polyfunctional isocyanates or epoxy compounds, dehydrocondensation products thereof with monofunctional or polyfunctional carboxylic acids, etc. In addition, it is also appropriate to use addition reaction products of unsaturated carboxylic acid esters or amides having an electrophilic substituent such as an isocyanate group or an epoxy group with monohydric or polyhydric alcohols, amides or thiols and substitution reaction products of unsaturated carboxylic acid esters or amides having a leaving substituent such as a halogen group or a tosyloxy group with monohydric or polyhydric alcohols, amines or thiols. As further examples, it is also possible to employ compounds prepared by substituting the unsaturated carboxylic acids as described above by unsaturated phosphonic acid, styrene, vinyl ether or the like.

As Particular examples of the monomers of the esters of aliphatic polyhydric alcohol compounds with unsaturated carboxylic acids, citation may be made of acrylic acid esters, e.g., ethylene glycol diacrylate, triethylene glycol diacrylate, 1,3-butanediol diacrylate, tetramethylene glycol diacrylate, propylene glycol diacrylate, neopentyl glycol diacrylate, trimethylolpropane triacrylate, trimethylolpropane tri(acryloyloxypropyl) ether, trimethylolethane triacrylate, hexanediol diacrylate, 1,4-cyclohexanediol diacrylate, tetraethylene glycol diacrylate, pentaerythritol diacrylate, pentaerythritol triacrylate, pentaerythritol tetraacrylate, dipentaerythritol diacrylate, dipentaerythritol hexaacrylate, sorbitol triacrylate, sorbitol tetraacrylate, sorbitol pentaacrylate, sorbitol hexaacrylate, tri(acryloyloxyethyl) isocyanurate, isocyanuric acid EO--denatured diactylate, isocyanuric acid EO-denatured triacrylate and polyester acrylate oligomers.

Examples of methacrylic acid esters include tetramethylene glycol dimethacrylate, triethylene glycol dimethacrylate, neopentyl glycol dimethacrylate, trimethylolpropane trimethacrylate, trimethylolethane trimethacrylate, ethylene glycol dimethacrylate, 1,3-butanediol dimethacrylate, hexanediol dimethacrylate, pentaerythritol dimethacrylate, pentaerythritol trimethacrylate, pentaerythritol tetramethacrylate, dipentaerythritol dimethacrylate, dipentaerythritol hexamethacrylate, sorbitol trimethacrylate, sorbitol tetramethacrylate, bis[p-(3-methacryloxy-2-hydroxypropoxy)phenyl]dimethylmethane and bis[p-(methacryloxyethoxy)phenyl]dimethylmethane.

Examples of itaconic acid esters include ethylene glycol diitaconate, propylene glycol diitaconate, 1,3-butanediol diitaconate, 1,4-butanediol diitaconate, tetramethylene glycol diitaconate, pentaerythritol diitaconate and sobritol tetraitaconate. Examples of crotonic acid esters include ethyleneglycol dicrotonate, tetramethylene glycol dicrotonate, pentaerythritol dicrotonate and sorbitol tetracrotonate. Examples of isocrotonic acid esters include ethyleneglycol diisocrotonate, pentaerythritol diisocrotonate and sorbitol tetraisocrotonate. Examples of maleic acid esters include ethyleneglycol dimaleate, triethylene glycol dimaleate, pentaerythritol dimaleate and sorbitol tetramaleate.

As other examples of the esters, use may be appropriately made of aliphatic alcohol type esters described in JP-B-51-47334 and JP-A-57-196231, those having an aromatic skeleton described in JP-A-59-5240, JP-A-59-5241 and JP-A-2-226149, those having an amino group described in JP-A-1-165613, etc. Furthermore, it is also possible to use mixtures of the ester monomers as described above.

Particular examples of themonomers of amides of aliphatic polyvalent amine compounds with unsaturated carboxylic acids include methylene bis-acrylamide, methylene bis-methacrylamide, 1,6-hexamethyelne bis-acrylamide, 1,6-hexamethyelne bis-methacrylamide, diethylenetriamine trisacrylamide, xylyene bisacrylamide, xylylene bismethacrylamide, etc. Other preferable examples of amide-type monomers include those having a cyclohexylene structure described in JP-B-54-21726.

Also, a urethane-based addition-polymerizable compound produced by using the addition reaction between isocyanate and a hydroxyl group can be appropriately used. Particular examples thereof include vinylurethane compounds having two or more polymerizable vinyl groups per molecule, which are obtained by adding a vinyl monomer having a hydroxyl group as represented by the following formula to a polyisocyanate compound having two or more isocyanate groups per molecule, as described in, for example, JP-B-48-41708.
CH₂═C(R₂₁)COOCH₂CH(R₂₂)OH (C-1)
wherein R₂₁ and R₂₂ represent each H or CH₃.

Moreover, use may be appropriately made of urethane acrylates described in JP-A-51-37193, JP-B-2-32293 and JP-B-2-16765, urethane compounds having an ethylene oxide-type skeleton described in JP-B-58-49860, JP-B-56-17654, JP-B-62-39417 and JP-B-62-39418, etc. Furthermore, heat-sensitive compositions having highly favorable photosensitive reaction speed can be obtained by using addition-polymerizable compounds having an amino structure or a sulfide structure in the molecule described in JP-A-63-277653, JP-A-63-260909 and JP-A-1-105238.

Additional examples of the polymerizable compound include polyester acrylates and polyfunctional acrylates and methacrylates such as epoxyacrylates obtained by reacting epoxy resins with (meth)acrylic acid which are described in JP-A-48-64138, JP-B-49-43191 and JP-B-52-30490. Furthermore, specific unsaturated compounds described in JP-B-46-43946, JP-B-1-40337 and JP-B-1-40336 and vinylphosphonic acid type compounds described in JP-A-2-25493 may be cited. In some cases, moreover, it is appropriate to use a structure having a perfluoroalkyl group as described in JP-A-61-22048. It is also possible to use light-hardening monomers and oligomers reported in Nippon Secchaku Kyokai-shi, vol. 20, No. 7, p. 300 to 308 (1984).

Details in using such a polymerizable compound (i.e., it structure, either using alone or combinedly, the addition level, etc.) can be arbitrarily selected depending on the purpose of use, for example, design of the performance of the a recording material of the lithographic printing plate precursor according to the invention. For example, selection may be made from the following viewpoints.

Concerning the photosensitization speed, it is preferable to employ a structure containing much unsaturated groups per molecule (preferably being bifunctional or higher in many cases). To elevate the strength in the image part (i.e., the hardened film), a trifunctional or higher compound is preferable. It is also effective to use a combination of compounds having different functional valencies and different polymerizable groups (for example, an acrylic acid ester, a methacrylic acid ester, a styrene-type compound and a vinyl ether-type compound) so as to control both of the photosensitivity and the strength.

Considering compatibility with other components in the recording layer (for example, a binder polymer, an initiator and a colorant) and dispersion properties, the selection and method of use of the polymerizable compound are highly important factors. For example, the compatibility can be improved in some cases by using a compound with a low purity or a combination of two or more compounds. It is also possible to select a specific structure in order to enhance the adhesiveness to a substrate or a protective layer as will be described hereinafter.

It is preferable that the content of the polymerizable composition in the image recording layer ranges from 5 to 80% by mass, still preferably from 25 to 75% by mass. Either one polymerizable compound or two or more thereof may be used. In using the polymerizable compound, moreover, its structure, composition and addition level can be appropriately selected from the viewpoints of the degree of polymerization initiation to oxygen, resolution, fogging, change in refraction index, surface adhesiveness and so on. It is also possible in some cases to employ such a layer structure and coating method as forming undercoating or overcoating.

[(D) Compound Having Carboxylate Group]

The polymerizable compound to be used in the invention is not particularly restricted. Thus, use may be preferably made of, for example, carboxylic acid compounds and polycarboxylic acid compounds described in International Patent Publication 048836/00 and International Patent Publication 12759/97.

As one of preferred embodiments thereof, monocarboxylic acid compounds represented by the following formula (I) can be cited.

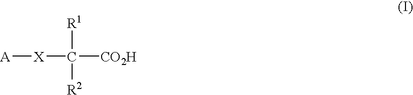

In the formula (I), A represents an aromatic group or a heterocyclic group. R¹ and R² independently represent each a hydrogen atom or a monovalent substituent, or R¹ and R², one of R¹ and R² and X, one of R¹ and R² and A, or A and X may be bonded to each other to form a cyclic structure. X represents a divalent linking group selected from among —O—, —S—, —SO₂—, —NH—, —N(R³)—, —CH₂—, —CH(R⁴)— and —C(R⁴)(R⁵)—, wherein R³, R⁴ and R⁵ independently represent each a hydrogen atom or a monovalent substituent.

As the aromatic group represented by A in the formula (I), a benzene ring, a ring formed by the fusion of two or three benzene rings and a ring formed by the fusion of a benzene ring with a 5-memebered unsaturated ring may be cited. Specific examples thereof include a phenyl group, a naphthyl group, an anthryl group, a phenanthryl group, an indenyl group, an acenaphthenyl group and a fluorenyl group. Among them, a phenyl group and a naphthyl group are still preferred.

The aromatic group may be optionally substituted. Examples of such substituted aromatic groups include substituted aryl groups as will be described hereinafter. Preferable examples of the substituent to be introduced herein include alkyl groups and substituted alkyl groups as will be described hereinafter and substituents as will be cited as examples of the substituent in the substituted alkyl groups.

Examples of the heterocyclic group represented by A include a pyrrole ring group, a furan ring group, a thiophene ring group, a benzopyrrole ring group, a benzofuran ring group, a benzothiophene ring group, a pyrazole ring group, an isoxazole ring group, an isothiazole ring group, an indazole ring group, a benzoisoxazole ring group, a benzoisothiazole ring group, an imidazole ring group, an oxazole ring group, a thiazole ring group, a benzimidazole ring group, a benzoxazole ring group, a benzothiazole ring group, a pyridine ring group, a quinoline ring group, an isoquinoline ring group, a pyridazine ring group, a pyrimidine ring group, a pyrazine ring group, a phthalazine ring group, a quinazoline ring group, a quinoxaline ring group, an acylidine ring group, a phenantridine ring group, a carbazole ring group, a purine ring group, a pyran ring group, a piperidine ring group, a morpholine ring group, an indole ring group, an indolidine ring group, a curomen ring group, a cinnoline ring group, an acridine ring group, a phenothiazine ring group, a tetrazole ring group, a triazine ring group and so on.

The heterocyclic group may be optionally substituted. Examples of the substituent include substituents as will be cited as examples of the substituent in the substituted aryl groups. Preferable examples of the substituent include alkyl groups and substituted alkyl groups as will be described hereinafter and substituents as will be cited as examples of the substituent in the substituted alkyl groups.

Examples of the monovalent substituents represented by R¹ and R² in the formula (I) include halogen atoms, an optionally substituted amino group, alkocycarbonyl groups, a hydroxyl group, ether groups, a thiol group, thiother groups, a silyl group, a nitro group, a cyano group and optionally substituted alkyl groups, alkenyl groups, alkynyl groups, aryl groups and heterocyclic groups.

As examples of the alkyl groups, linear, branched and cyclic alkyl groups having from 1 to 20 carbon atoms may be cited. Specificexamples thereofincludemethyl, ethyl, propyl, butyl, pentyl, hexyl, heptyl, octyl, nonyl, decyl, undecyl, dodecyl, tridecyl, hexadecyl, octadecyl, eiocsyl, isopropyl, isobutyl, s-butyl, t-butyl, isopentyl, neopentyl, 1-methylbutyl, isohexyl, 2-ethylhexyl, 2-methylhexyl, cyclohexyl, cyclopentyl and 2-norbornyl groups. Among these groups, linear alkyl groups having from 1 to 12 carbon atoms, branched alkyl groups having from 3 to 12 carbon atoms and cyclic alkyl groups having from 5 to 10 carbon atoms are still preferable.

As the substituent which can be introduced into the alkyl group, use can be made of a monovalent nonmetallic atom group excluding hydrogen. Preferable examples thereof include halogen atoms (—F, —Br, —Cl, —I), a hydroxyl group, alkoxy groups, aryloxy groups, a mercapto group, alkylthio groups, arylthio groups, alkyldithio groups, aryldithio groups, an amino group, N-alkylamino groups, N,N-dialkylamino groups, N-arylamino groups, N,N-diarylamino groups, N-alkyl-N-arylamino groups, acyloxy groups, a carbamoyloxy group, N-alkylcarbamoyloxy groups, N-arylcarbamoyloxy groups, N,N-dialkylcarbamoyloxy groups, N,N-diarylcarbamoyloxy groups, N-alkyl-N-arylcarbamoyloxy groups, alkylsulfoxy groups, arylsulfoxy groups, acylthio groups, acylamino groups, N-alkylacylamino groups, N-arylacylamino groups, a ureido group, N′-alkylureido groups, N′,N′-dialkylureido groups, N′-arylureido groups, N′,N′-diarylureido groups, N′-alkyl-N′-arylureido groups, N-alkylureido groups, N-arylureido groups, N′-alkyl-N-alkylureido groups, N′-alkyl-N-arylureido groups, N′,N′-dialkyl-N-alkylureido groups, N′,N′-dialkyl-N-arylureido groups, N′-aryl-N-alkylureido groups, N′-aryl-N-arylureido groups, N′,N′-diaryl-N-alkylureido groups, N′,N′-diaryl-N-arylureido groups, N′-alkyl-N′-aryl-N-alkylureido groups, N′-alkyl-N′-aryl-N-arylureido groups, alkoxycarbonylamino groups, aryloxycarbonylamino groups, N-alkyl-N-alkoxycarbonylamino groups, N-alkyl-N-aryloxycarbonylamino groups, N-aryl-N-alkoxycarbonylamino groups, N-aryl-N-aryloxycarbonylamino groups, a formyl group, acyl groups, a carboxyl group and conjugate base groups thereof, alkoxycarbonyl groups, aryloxycarbonyl groups, a carbamoyl group, N-alkylcarbamoyl groups, N,N-dialkylcarbamoyl groups, N-arylcarbamoyl groups, N,N-diarylcarbamoyl groups, N-alkyl-N-arylcarbamoyl groups, alkylsulfinyl groups, arylsulfinyl groups, alkylsulfonyl groups, arylsulfonyl groups, a sulfo group (—SO₃H) and conjugate base groups thereof (called sulfonate groups), alkoxysulfonyl groups, aryloxysulfonyl groups, a sulfinamoyl group, N-alkylsulfinamoyl groups, N,N-dialkylsulfinamoyl groups, N-arylsulfinamoyl groups, N,N-diarylsulfinamoyl groups, N-alkyl-N-arylsulfinamoyl groups, a sulfamoyl group, N-alkylsulfamoyl groups, N,N-dialkylsulfamoyl groups, N-arylsulfamoyl groups, N,N-diarylsulfamoyl groups, N-alkyl-N-arylsulfamoyl groups, a phosphono group (—PO₃H₂) and conjugated base groups thereof (called phosphonate groups), dialkylphosphono groups (—PO₃(alkyl)₂), diarylphosphono groups (—PO₃(aryl)₂), alkylarylphosphono groups (—PO₃(alkyl)(aryl)), monoalkylphosphono groups (—PO₃H(alkyl)) and conjugate base groups thereof (called alkylphosphonate groups), monoarylphosphono groups (—PO₃H(aryl)) and conjugate base groups thereof (called arylphosphonate groups), a phosphonoxy group (—PO₃H₂) and conjugate base groups thereof (called phosphonatoxy groups), dialkylphosphonoxy groups (—OPO₃(alkyl)₂), diarylphosphonoxy groups (—OPO₃(aryl)₂), alkylarylphosphonoxy groups (—OPO₃(alkyl)(aryl)), monoalkylphosphonoxygroups (—OPO₃H(alkyl)) andconjugatebase groups thereof (called alkylphosphonatoxy groups), monoarylphosphonoxy groups (—OPO₃H(aryl)) and conjugate base groups thereof (called arylphosphonatoxy groups), a cyano group, a nitro group, aryl groups, alkyenyl groups, alkynyl groups, heterocyclic groups, silyl groups and so on.

Examples of the alkyl group in these substituent include the alkyl groups as cited above. Specific examples of the aryl group in these substituents includephenyl, biphenyl, naphthyl, tolyl, xylyl, mesityl, cumenyl, chlorophenyl, bromophenyl, chloromethylphenyl, hydroxyphenyl, methoxyphenyl, ethoxyphenyl, phenoxyphenyl, acetoxyphenyl, benzoyloxyphenyl, methylthiophenyl, phenylthiophenyl, methylaminophenyl, dimethylaminophenyl, acetylaminophenyl, carboxyphenyl, methoxycarbonylphenyl, ethoxyphenylcarbonyl, phenoxycarbonylphenyl, N-phenylcarbamoylphenyl, cyanophenyl, sulfonaphthophenyl, phosphonophenyl and phosphonatophenyl groups.

Examples of the alkenyl group include vinyl, 1-propenyl, 1-butenyl, cinnamyl and 2-chloro-1-ethenyl groups. Examples of the alkynyl group include ethynyl, 1-propynyl, 1-butynyl and trimethylsilylethynyl groups.

Examples of R⁰¹ in an acyl group (R⁰¹CO) include a hydrogen atom and the above-described alkyl and aryl groups. Among these substituents, still preferable ones include halogen atoms (—F, —Br, —Cl, —I), alkoxy groups, aryloxy groups, alkylthio groups, arylthiogroups, N-alkylaminogroups, N,N-dialkylaminogroups, acyloxy groups, N-alkylcarbamoyloxy groups, N-arylcarbamoyloxy groups, acylamino groups, formyl groups, acyl groups, a carboxyl group, alkoxycarbonyl groups, aryloxycarbonyl groups, a carbamoyl group, N-alkylcarbamoyl groups, N,N-dialkylcarbamoyl groups, N-arylcarbamoyl groups, N-alkyl-N-arylcarbamoyl groups, a sulfo group, a sulfonate group, a sulfamoyl group, N-alkylsulfamoyl groups, N,N-dialkylsulfamoyl groups, N-arylsulfamoyl groups, N-alkyl-N-arylsulfamoyl group, a phosphono group, a phosphonate group, dialkylphosphono groups, diarylphopsphono groups, monoalkylphosphono groups, alkylphosphonate groups, monoarylphosphono groups, arylphosphonate groups, a phosphonoxy group, a phosphonatoxy group, aryl groups and alkenyl groups.

As the heterocyclic group, a pyridyl group, a piperidinyl group and soon may be cited. As a silyl group, a trimethylsilyl group and so on may be cited.

As the alkylene group in the substituted alkylene group, on the other hand, divalent organic residues prepared by removing one of hydrogen atoms in an alkyl group having from 1 to 20 carbon atoms as described above may be cited. Preferable examples thereof include linear alkylene groups having from 1 to 12 carbon atoms, branched alkylene atoms having from 3 to 12 carbon atoms and cyclic alkylene atoms having from 5 to 10 carbon atoms. Preferable examples of such substituted alkylene groups obtained by combining a substituent with an alkylene group include chloromethyl, bromomethyl, 1-chloroethyl, trifluoromethyl, methoxymethyl, isopropoxymethyl, butoxymethyl, s-butoxymethyl, methoxyethoxyethyl, allyloxymethyl, phenoxymethyl, methylthiomethyl, tolylthiomethyl, pyridylmethyl, tetramethylpiperidinylmethyl, N-acetyltetramethylpiperidinylmethyl, trimethylsilylmethyl, methoxyethyl, ethylaminoethyl, diethylaminopropyl, morpholinopropyl, acetyloxymethyl, benzoyloxymethyl, N-cyclohexylcarbamoyloxyethyl, N-phenylcarbamoyloxyethyl, acetylaminoethyl, N-methylbenzoylaminopropyl, 2-oxoethyl, 2-oxopropyl, carboxypropyl, methoxycarbonylethyl, allyloxycarbonylbutyl, chlorophenoxycarbonylmethyl, carbamoylmethyl, N-methylcarbamoylethyl, N,N-dipropylcarbamoylmethyl, N(methoxyphenyl)carbamoylethyl, N-methyl-N-(sulfonyl)carbamoylmethyl, sulfobutyl, sulfonatobutyl, sulfamoylbutyl, N-ethylsulfamoylmethyl, N,N-dipropylsulfamoylpropyl, N-tolylsulfamoylpropyl, N-methyl-N-(phosphonophenyl)sulfamoyloctyl, phosphonobutyl, phosphonatohexyl, diethylphosphonobutyl, diphenylphosphonopropyl, methylphosphonobutyl, methylphosphonatobutyl, tolylphosphonohexyl, tolylphosphonatohexyl, phosphonoxypropyl, phosphonatoxybutyl, benzyl, phenethyl, α-methylbenzyl, 1-methyl-1-phenylethyl, p-methylbenzyl, cinnamyl, allyl, 1-propenylmethyl, 2-butenyl, 2-methylallyl, 2-methylpropenyl, 2-propynyl, 2-butynyl and 3-butynyl groups and so on.

As the aryl group, a benzene ring, a ring formed by the fusion of two or three benzene rings and a ring formed by the fusion of a benzene ring with a 5-memebered unsaturated ring may be cited. Specific examples thereof include a phenyl group, a naphthyl group, an anthryl group, a phenanthryl group, an indenyl group, an acenaphthenyl group and a fluorenyl group. Among them, a phenyl group and a naphthyl group are still preferred.

As the substituted aryl group, use can be made of the above-described aryl groups having a group consisting of a monovalent nonmetallic atom groups other than a hydrogen atom on a ring-forming carbon atom. Preferable examples of the substituent include the above-described alkyl groups and substituted alkyl groups and those cited above as examples of the substituent in the substituted alkyl groups.

Specific examples of the preferred substituted aryl group includebi phenyl, tolyl, xylyl, mesityl, cumenyl, chlorophenyl, bromophenyl, fluorophenyl, cyclomethylphenyl, trifluoromethylphenyl, hydroxyphenyl, methoxyphenyl, methoxyethoxyphenyl, allyloxyphenyl, phenoxyphenyl, methylthiophenyl, tolylthiophenyl, ethylaminophenyl, diethylaminophenyl, morpholinophenyl, acetyloxyphenyl, benzoyloxyphenyl, N-cyclohexylcarbamoyloxyphenyl, N-phenylcarbamoyloxyphenyl, acetylaminophenyl, N-methylbenzoylaminophenyl, carboxyphenyl, methoxycarbonylphenyl, allyoxycarbonylphenyl, chlorophenoxycarbonylphenyl, carbamoylphenyl, N-methylcarbamoylphenyl, N,N-dipropylcarbamoylphenyl, N-(methoxyphenyl)carbamoylphenyl, N-methyl-N-(sulfophenyl)carbamoylphenyl, sulfophenyl, sulfonatophenyl, sulfamoylphenyl, N-ethylsulfamoylphenyl, N,N-dipropylsulfamoylphenyl, N-tolylsulfamoylphenyl, N-methyl-N-(phosphonophenyl)sulfamoylphenyl, phosphonophenyl, phosphonatophenyl, diethylphosphonophenyl, diphenylphosphonophenyl, methylphosphonophenyl, methylphosphonatophenyl, tolylphosphonophenyl, tolylphosphonatophenyl, allylphenyl, 1-propenylmethylphenyl, 2-butenylphenyl, 2-methylallylphenyl, s-methylpropenylphenyl, 2-propynylphenyl, 2-butynylphenyl and 3-butynylphenyl groups and so on.

As an alkenyl group, a substituted alkenyl group, an alkynyl group and a substituted alkynyl group (—C(R⁰²)═C(R⁰³)(R⁰⁴) and —C≡C(R⁰⁵), use can be made of those wherein R⁰², R⁰³, R⁰⁴ and R⁰⁵ are each a monovalent nonmetallic atom group. Preferable examples of R⁰², R⁰³, R⁰⁴ and R⁰⁵ include a hydrogen atom, halogen atoms, alkyl groups, substituted alkyl groups, aryl groups and substituted aryl groups. As specific examples thereof, the above-described ones can be cited. Still preferable examples of R⁰², R⁰³, R⁰⁴ and R⁰⁵ include a hydrogen atom, halogen atoms and linear, branched or cyclic alkyl groups having from 1 to 10 carbon atoms.

Specifically preferable examples of the alkenyl group, substituted alkenyl group, alkynyl group and substituted alkynyl group include vinyl, 1-propenyl, 1-butenyl, 1-pentenyl, 1-hexenyl, 1-octenyl, 1-methyl-1-propenyl, 2-methyl-1-propenyl, 2-methyl-1-butenyl, 2-phenyl-1-ethenyl, 2-chloro-1-ethenyl, ethynyl, 1-propynyl, 1-butynyl and phenylethynyl groups.

As examples of a heterocyclic group, pyridyl group and so on cited as examples of the substituent of the substituted alkyl group may be cited.

As the above-described substituted oxy group (R⁰⁶O—), use can be made of a group wherein R⁰⁶ is a monovalent nonmetallic atom group other than a hydrogen atom. Preferable examples of the substituted oxy group include alkoxy, aryloxy, acyloxy, carbamoyloxy, N-alkylcarbamoyloxy, N-arylcarbamoyloxy, N,N-dialkylcarbamoyloxy, N,N-diarylcarbamoyloxy, N-alkyl-N-arylcarbamoyloxy, alkylsulofxy, arylsulfoxy, phosphonoxy and phosphonatoxy groups. As examples of an alkyl group and an aryl group in these groups, the above-described alkyl groups, substituted alkyl groups, aryl groups and substituted aryl groups may be cited. As an acyl group (R⁰⁷CO—) in the acyloxy group, those wherein R⁰⁷ is one of the alkyl groups, substituted alkyl groups, aryl groups and substituted aryl groups may be cited. Among these substituents, alkoxy, aryloxy, acyloxy and arylsulfoxy groups are preferred. Specific examples of preferable substituted oxy groups include methoxy, ethoxy, propyloxy, isopropyloxy, butyloxy, pentyloxy, hexyloxy, dodecyloxy, benzyloxy, allyloxy, phenethyloxy, carboxyethyloxy, methoxycarbonylethyloxy, ethoxycarbonylethyloxy, methoxyethoxy, phenoxyethoxy, methoxyethoxyethoxy, ethoxyethoxyethoxy, morpholinoethoxy, morpholinopropyloxy, allyloxyethoxyethoxy, phenoxy, tolyloxy, xylyloxy, mesityloxy, cumenyloxy, methoxyphenyloxy, ethoxyphenyloxy, chlorophenyloxy, bromophenyloxy, acetyloxy, benzoyloxy, naphthyloxy, phenylsulfonyloxy, phosphonoxy and phosphonatoxy groups and so on.

As a substituted amino group containing an amido group (R⁰⁸NH—, (R⁰⁹)(R⁰¹⁰)N—), use can be made of those wherein R⁰⁸, R⁰⁹ and R¹⁰ are each a monovalent nonmetallic atom group excluding a hydrogen atom. R⁰⁹ and R¹⁰ may be bonded to form a ring together. Preferable examples of the substituted amino group include N-alkylamino, N,N-dialkylamino, N-arylamino, N,N-diarylamino, N-alkyl-N-arylamino, acylamino, N-alkylacylamino, N-arylacylamino, ureido, N′-alkylureido, N′,N′-dialkylureido, N′-arylureido, N′,N′-diarylureido, N′-alkyl-N′-arylureido, N-alkylureido, N-arylureido, N′-alkyl-N-alkylureido, N′-alkyl-N-arylureido, N′,N′-dialkyl-N-alkylureido, N′-alkyl-N′-arylureido, N′,N′-dialkyl-N-alkylureido, N′,N′-dialkyl-N′-arylureido, N′-aryl-N-alkylureido, N′-aryl-N-arylureido, N′,N′-diaryl-N-alkylureido, N′,N′-diaryl-N-arylureido, N′-alkyl-N′-aryl-N-alkylureido, N′-alkyl-N′-aryl-N-arylureido, alkoxycarbonylamino, aryloxycarbonylamino, N-alkyl-N-alkoxycarbonylamino, N-alkyl-N-aryloxycarbonylamino, N-aryl-N-alkoxycarbonylamino and N-acryl-N-aryloxycarbonylamino groups. As examples of an alkyl group and an aryl group in these groups, the above-described alkyl groups, substituted alkyl groups, aryl groups and substituted aryl groups may be cited. In an acyl group (R⁰⁷CO—) in the acylamino, N-alkylacylamino and N-arylacylamino groups, R⁰⁷ has the same meaning as described above. Among these groups, N-alkylamino, N,N-dialkylamino, N-arylamino and acylamino groups are preferred. Specific examples of preferred substituted amino groups include methylamino, ethylamino, diethylamino, morpholino, piperidino, pyrrolidino, phenylamino, benzoylamino and acetylamino groups and so on.

As a substituted sulfonyl group (R⁰¹¹—SO₂—), use can be made of those wherein R⁰¹¹ is a monovalent nonmetallic atom group. Still preferable examples thereof include alkylsulfonyl and arylsulfonyl groups. As examples of an alkyl group and an aryl group therein, the above-described alkyl, substituted alkyl, aryl and substituted aryl groups may be cited. Specific examples of the substituted sulfonyl group include butylsulfonyl, phenylsulfonyl and chlorosulfonyl groups and so on.

As described above, a sulfonate group (—SO₃—) means a conjugated basic anion group of a sulfo group (—SO₃). In usual, it is preferably employed together with a counter cation. As examples of the counter cation, those commonly known in the art such as various oniums (ammoniums, sulfoniums, phosphoniums, iodoniums, adiniums, etc.) and metal ions (Na⁺, K⁺, Ca²⁺, Zn²⁺, etc.) may be cited.

As a substituted carbonyl group (R⁰¹³—C—), use can be made of those wherein R¹⁰³ is a monovalent nonmetallic atom group. Preferable examples of the substituted carbonyl group include formyl, acyl, carboxyl, alkoxycarbonyl, aryloxycarbonyl, carbamoyl, N-alkylcarbamoyl, N,N-dialkylcarbamoyl, N-arylcarbamoyl and N,N-diarylcarbamoyl, N-alkyl-N′-arylcarbamoyl groups. As examples of analkyl group and an aryl group therein, the above-described alkyl, substituted alkyl, aryl and substituted aryl groups may be cited. Among them, still preferable examples of the substituted carbonyl group include formyl, acyl, carboxyl, alkoxycarbonyl, aryloxycarbonyl, carbamoyl, N-alkylcarbamoyl, N,N-dialkylcarbamoyl and N-arylcarbamoyl groups. Formyl, acyl, alkoxycarbonyl and aryloxycarbonyl groups are still preferable. Specific examples of the preferable substituted carbonyl group include formyl, acetyl, benzoyl, carboxymethyl, methoxycarbonyl, ethoxycarbonyl, allyloxycarbonyl, dimethylaminophenylethenylcarbonyl, methoxycarbonylmethoxycarbonyl, N-methylcarbamoyl, N-phenylcarbamoyl, N,N-diethylcarbamoyl and morpholinocarbamoyl groups and so on.

As a substituted sulfinyl group (R014-SO—), use can be made of those wherein R⁰¹⁴ is a monovalent nonmetallic atom group. Preferable examples thereof include alkylsulfinyl, arylsulfinyl, sulfinamoyl, N-alkylsulfinamoyl, N,N-dialkylsulfinamoyl, N-arylsulfinamoyl, N,N-diarylsulfinamoyl and N-alkyl-N-arylsulfinamoyl groups. As examples of an alkyl group and an aryl group therein, the above-described alkyl, substituted alkyl, aryl and substituted aryl groups may be cited. Among these groups, alkylsulfinyl groups and arylsulfinyl groups are still preferable. Specific examples of the substituted sulfinyl group include hexylsulfinyl, benzylsulfinyl and tolylsulfinyl groups and so on.

A substituted phosphono group means a phosphono group wherein one or more hydroxyl groups on the phosphono group are substituted by other organic oxo group(s). Preferable examples thereof include the above-described dialkylphosphono, diarylphosphono, alkylarylphosphono, monoalkylphosphono and monoarylphosphono groups. Among these groups, dialkylphosphono groups and diarylphosphono groups are still preferable. Specific examples thereof include diethylphosphono, dibutylphosphono and diphenylphosphono groups and so on.

As described above, a phosphonate group (—PO₃H₂—, —PO₃H—) means a conjugated base anion derived from the first acid dissociation or second acid dissociation of a phosphono group (—PO₃H₂). In usual, it is preferably employed together with a counter cation. As examples of the counter cation, those commonly known in the art such as various oniums (ammoniums, sulfoniums, phosphoniums, iodoniums, adiniums, etc.) andmetal ions (Na⁺, K⁺, Ca²⁺, Zn²⁺, etc.) may be cited.

A substituted phosphonate group means a conjugated base anion group wherein a hydroxyl group of a substituted phosphono group as described above is substituted by an organic oxo group. Specific examples thereof include conjugated bases of monoalkylphosphono (—PO₃H(alkyl)) and nonoarylphosphono (—PO₃H(aryl)) groups.

Next, X in the above-described formula (I) will be illustrated. X represents a divalent linking group selected from among —O—, —S—, —SO₂—, —NH—, —N(R³)—, —CH₂—, —CH(R⁴)— and —C(R⁴)(R⁵)—. Among all, —NH—, —N(R³)—, —CH₂—, —CH(R⁴)— and —C(R⁴)(R⁵)— are preferable from the viewpoint of sensitivity. —NH— and —N(R³)— are still preferable and —N(R³)— is the most desirable from the viewpoints of sensitivity and storage stability.

In the above X, R³, R⁴and R⁵ independently represent each a hydrogen atom or a monovalent substituent. Such a monovalent substituent has the same meaning as R¹ and R² in the above-described formula (I).

As R³, an optionally substituted alkyl, alkenyl, alkynyl, aryl or heterocyclic group is particularly preferable. It is also preferable that R³ has at least one of —CO₂— and —CON(R⁸)— in its structure. The most desirable structures of R³ are those represented by the following formulae.

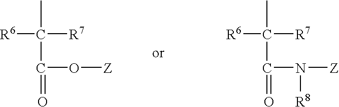

In the above formulae, R⁶, R⁷ and R⁸ independently represent each a hydrogen atom or a monovalent substituent, and Z represents a monovalent substituent. These monovalent substituents have the same meaning as defined with respect to R¹ or R² in the formula (I) as described above.

The monovalent substituents represented by R⁴ and R⁵ have the same meaning as defined with respect to R¹ or R² in the formula (I) as described above.

Next, specific examples (A-1) to (A-87) of the monocarboxylic acid compound represented by the formula (I) will be presented, though the invention is not restricted thereto.

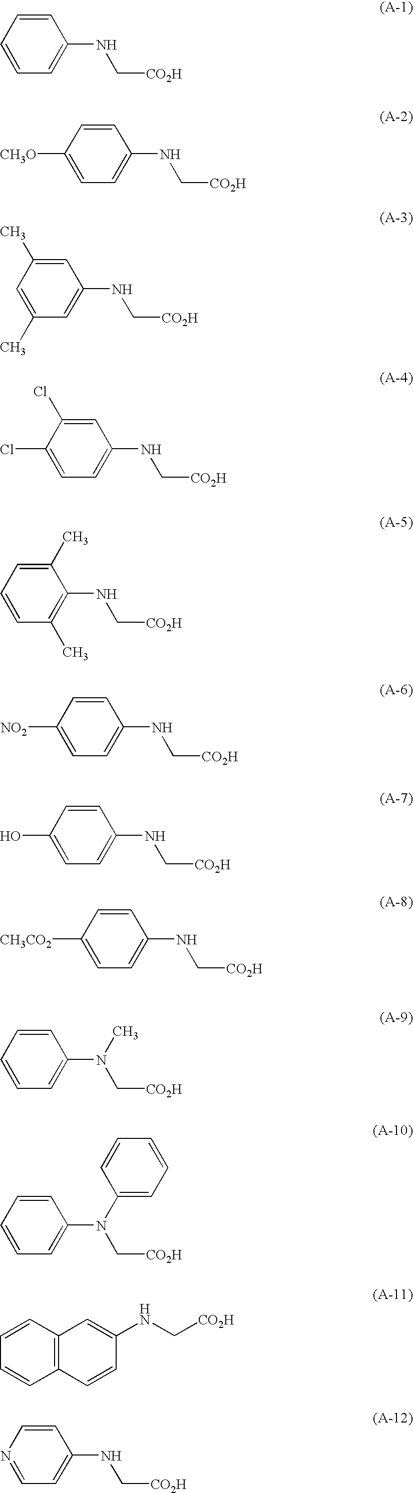

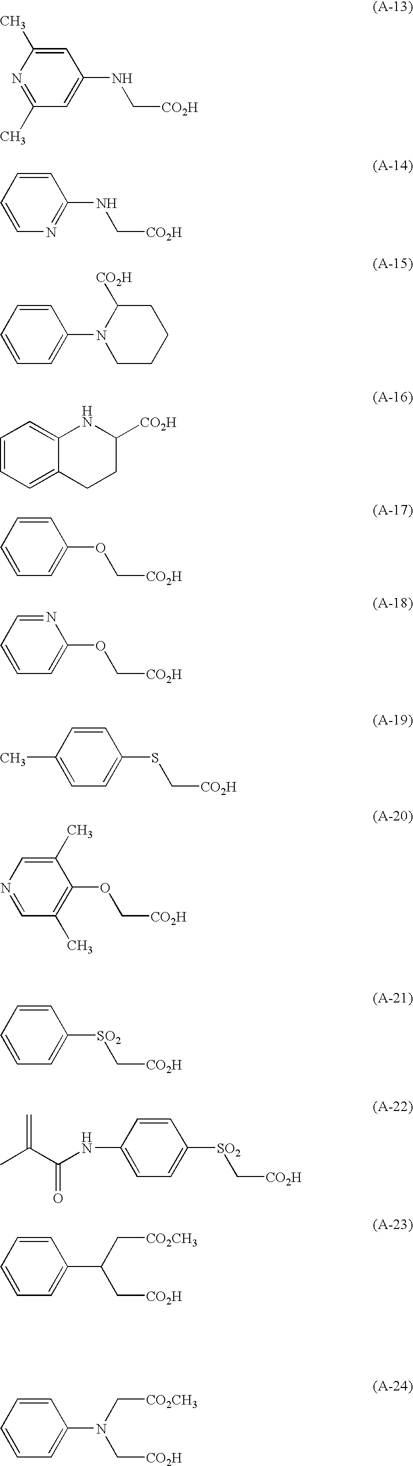

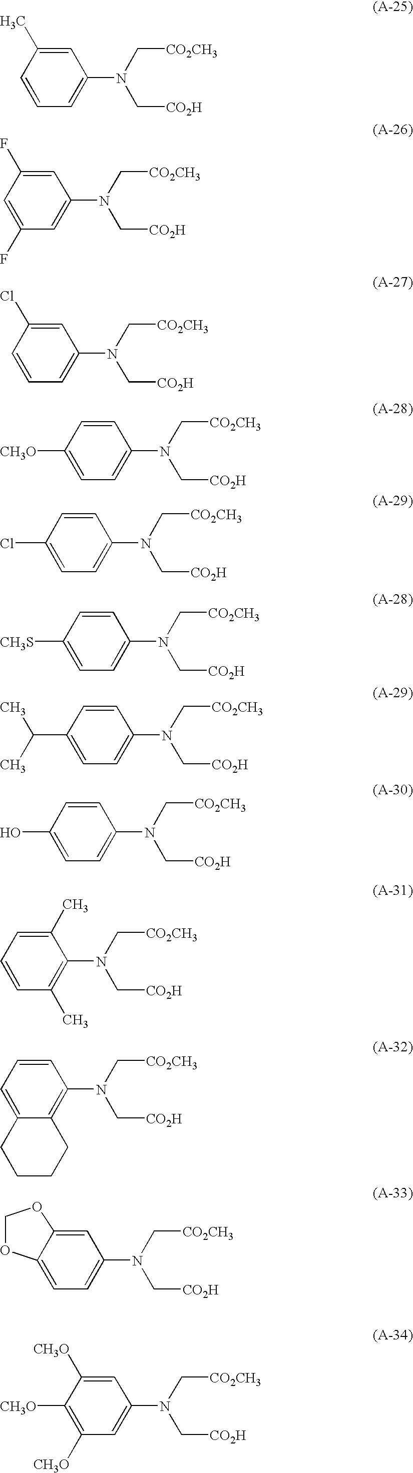

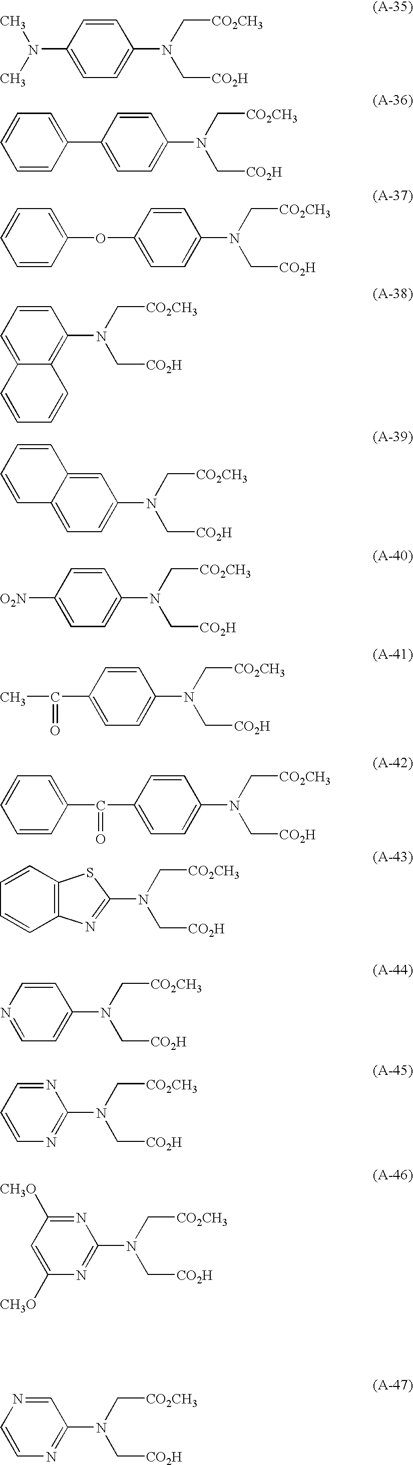

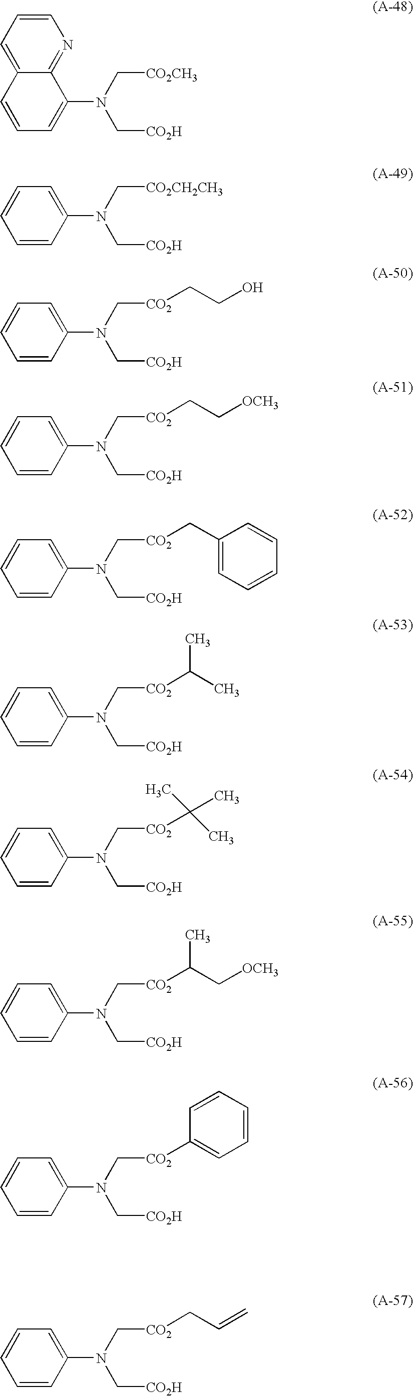

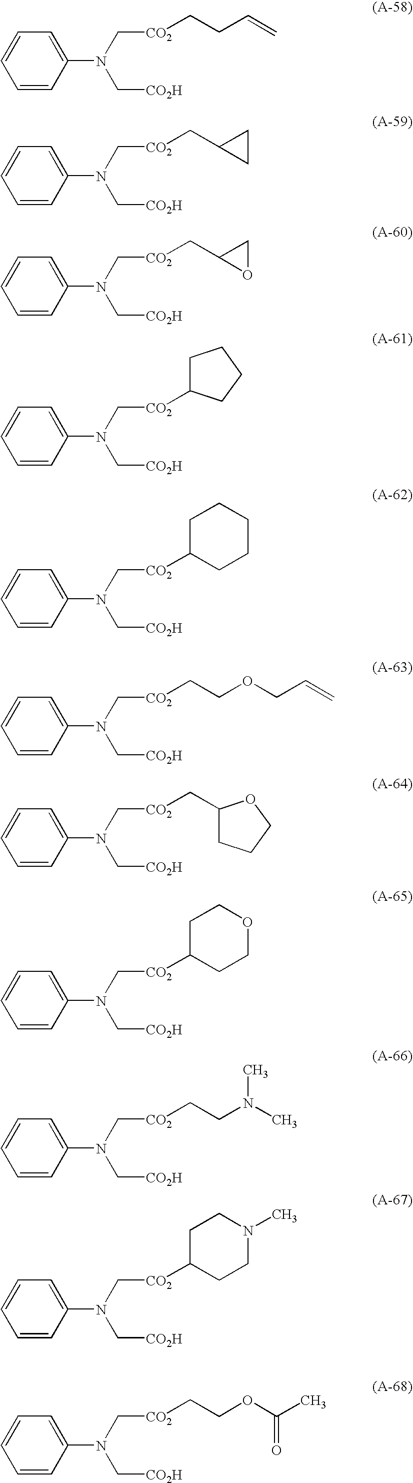

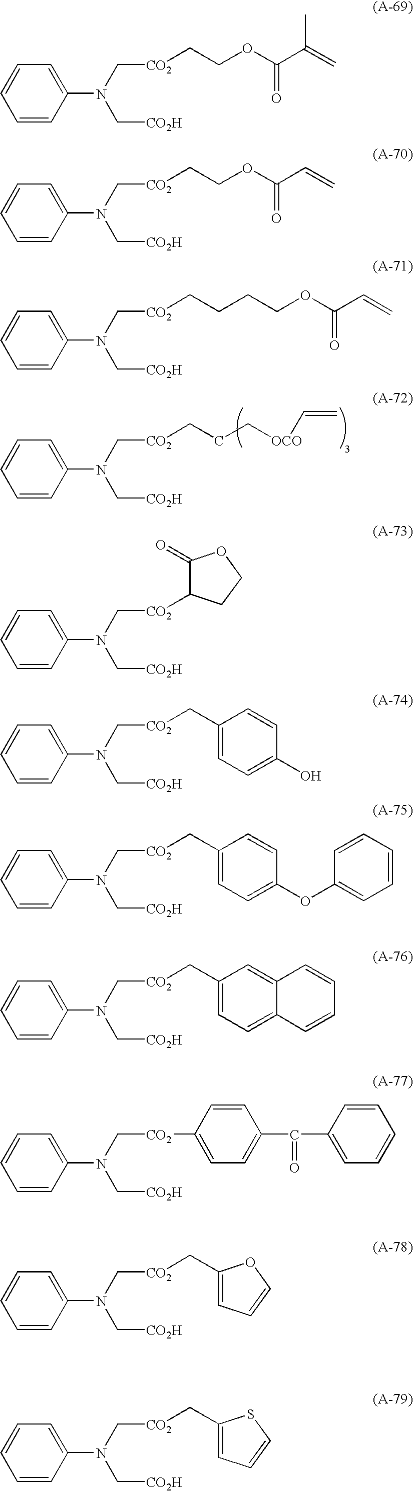

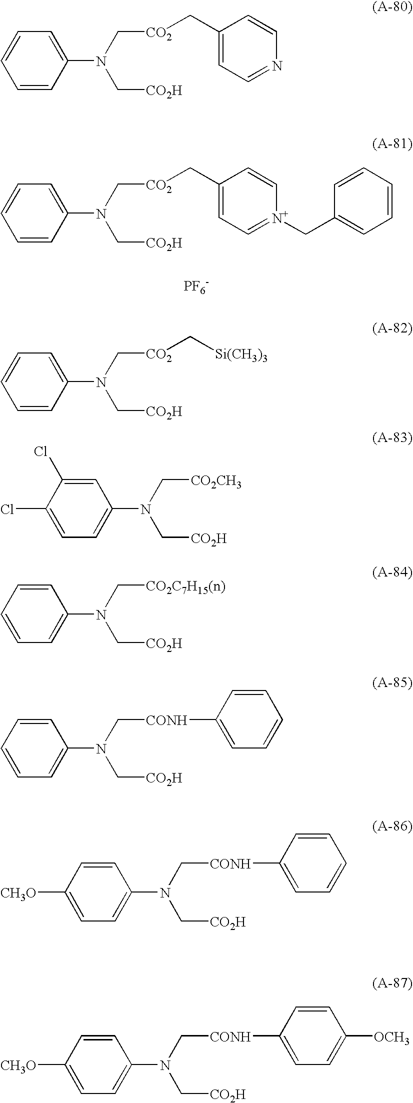

Next, a typical example of a method of synthesizing the compound having carboxylate group according to the invention will be presented, though the invention is not restricted thereto.

<Synthesis of Compound (A-24)>

Under a nitrogen gas stream, 62.8 g of N-phenylimidinoacetic acid was introduced into a 2 L round-bottomed flask and dissolved in 500 mL of toluene. After adding 32.0 g of acetic anhydride, the mixture was heated and refluxed while stirring. After 1 hour, it was cooled to room temperature and then 3 L of hexane was added thereto while stirring to allow precipitation. After filtering, 52.0 g of N-phenylimidinoacetic anhydride was obtained.

Next, 5.1 g of the N-phenylimidinoacetic anhydride obtained above was introduced into a 200 mL round-bottomed flask under a nitrogen gas stream. After adding 60 mL of methanol, the mixture was stirred at room temperature for 6 hours and then the solvent was distilled off. The residue was purified by silica gel chromatography (elution solvent: hexane/ethyl acetate) to give 5.7 g of compound (A-24). The product was identified as compound (A-24) based on its NMR spectrum, IR spectrum and mass spectrum.

<Synthesis of Compound (A-52)>

Under a nitrogen gas stream, 62.8 g of N-phenylimidinoacetic acid was introduced into a 2 L round-bottomed flask and dissolved in 500 mL of toluene. After adding 32.0 g of acetic anhydride, the mixture was heated and refluxed while stirring. After 1 hour, it was cooled to room temperature and then 3 L of hexane was added thereto while stirring to allow precipitation. After filtering, 52.0 g of N-phenylimidinoacetic anhydride was obtained.

Next, 5.1 g of the N-phenylimidinoacetic anhydride obtained above was introduced into a 200 mL round-bottomed flask under a nitrogen gas stream. After adding 50 mL of benzyl alcohol, the mixture was stirred at room temperature for 8 hours and then the solvent was distilled off. The residue was purified by silica gel chromatography (elution solvent: hexane/ethyl acetate) to give 7.2 g of compound (A-52). The product was identified as compound (A-52) based on its NMR spectrum, IR spectrum and mass spectrum.

<Synthesis of Compound (A-55)>

Under a nitrogen gas stream, 62.8 g of N-phenylimidinoacetic acid was introduced into a 2 L round-bottomed flask and dissolved in 500 mL of toluene. After adding 32.0 g of acetic anhydride, the mixture was heated and refluxed while stirring. After 1 hour, it was cooled to room temperature and then 3 L of hexane was added thereto while stirring to allow precipitation. After filtering, 52.0 g of N-phenylimidinoacetic anhydride was obtained.

Next, 5.1 g of the N-phenylimidinoacetic anhydride obtained above was introduced into a 200 mL round-bottomed flask under a nitrogen gas stream. After adding 50 mL of 1-methoxy-2-propanol, the mixture was stirred at room temperature for 4 hours and then the solvent was distilled off. The residue was purified by silica gel chromatography (elution solvent: hexane/ethyl acetate) to give6.0 g of compound (A-55). The product was identified as compound (A-55) based on its NMR spectrum, IR spectrum and mass spectrum.

Either one of the compounds having carboxylate group according to the invention or a mixture of two or more thereof may be used. Such a compound having carboxylate group maybe added in an amount of from 0.1 to 70% by mass, preferably from 0.5 to 50% by mass and still preferably from 1 to 30% by mass based on the total solidmatters constituting the image recording layer. In the case where the addition level is 0.1% by mass or more, a sufficient effect of elevating the sensitivity can be established. In the case where the addition level does not exceed 70% by mass, favorable onboard development can be obtained and favorable film properties can be also obtained before and after hardening.

[(E) Binder Polymer]

In the invention, it is possible to use a binder polymer in order to, for example, improve the filmproperties and onboard development of the image recording layer. As the binder polymer, use may be made of publicly known ones without particular restriction. It is preferable to use a linear organic high-molecular weight polymer having film properties. Examples of such binder polymer include acrylic resins, polyvinylacetal resins, polyurethane resins, polyurea resins, polyimide resins, polyamide resins, epoxy resins, methacrylic resins, polystyrene resins, novolak type phenolic resins, polyester resins, synthetic rubbers, natural rubbers and so on.

To improve the film strength in an image part, a crosslinkable binder polymer is preferable. To make a binder polymer crosslinkable, a crosslinkable functional group such as an ethylenic unsaturated bond is introduced into the main chain or side chain of the polymer. Such a crosslinkable functional group may be introduced either by copolymerization or a polymer reaction.

As examples of the polymer having an ethylenic unsaturated bond in the main chain of its molecule, poly-1,4-butadiene, poly-1,4-isoprene, etc. may be cited.

As examples of the polymer having an ethylenic unsaturated bondin the side chain of its molecule, polymers which are acrylic acid or methacrylic acid esters or amides and in which at least a part of the ester or amide residue (i.e., R in —COOR or CONHR) has an ethylenic unsaturated bond may be cited.

Examples of the residue having ethylenic unsaturated bond (R as described above) include —(CH₂)ₙCR⁴¹═CR⁴²R⁴³, —(CH₂O)ₙCH₂CR⁴¹═CR⁴²R⁴³, —(CH₂CH₂O)ₙCH₂CR⁴¹═CR⁴²R⁴³, —(CH₂)ₙNH—CO—O—CH₂CR⁴¹═CR⁴²R⁴³, —(CH₂)ₙ—O—CO—CR⁴¹═CR⁴²R⁴³ and —(CH₂CH₂O)ₙX (wherein R⁴¹ to R⁴³ represent each a hydrogen atom, a halogen atom or an alkyl group, an aryl group, an alkoxy group or an aryloxy group having from 1 to 20 carbon atoms, or R⁴¹ and R⁴² or R⁴³ may be bonded to form a ring together; n is an integer of from 1 to 10; and X represents a dicyclopentadienyl group).

Specific examples of the ester residue include —CH₂CH═CH₂, —CH₂CH₂O—CH₂CH═CH₂, —CH₂C(CH₃)═CH₂, —CH₂CH═CH—C₆H₅, —CH₂CH₂OCOOCH═CH—C₆H₅, —CH₂CH₂OCOC(CH₃)═CH₂, —CH₂CH₂OCOCH═CH₂, —CH₂CH₂—NHCOO—CH₂CH═CH₂ and CH₂CH₂O—X (wherein X represents a dicyclopentadienyl group).

Specific examples of the amide residue include —CH₂CH═CH₂, —CH₂CH₂—Y (wherein Y represents a cyclohexene group) and —CH₂CH₂—OCO—CH═CH₂.

Crosslinkage of the crosslinkable polymer proceeds, for example, as follows. A free radical (a polymerization-initiating radical or a polymerization-developing radical) attaches to the crosslinkable functional group and thus crosslinkage is formed among polymer molecules either directly or mediated by a polymer chain of the polymerizable compound, thereby causing hardening. Alternatively, an atom in the polymer (for example, a hydrogen atom onthe carbon atom adjacent to the functional crosslinkable group) is withdrawn by a free radical to form a polymer radical. Then such polymer radicals bind to each other to form crosslinkage among polymer molecules, thereby causing hardening.

The content of the crosslinkable group (the content of radical-polymerizable unsaturated double bond determined by iodine titration) in the binder polymer ranges preferably from 0.1 to 10.0 mmol, still preferably from 1.0 to 7.0 mmol and most desirably from 2.0 to 5.5 mmol pr gram of the binder polymer. So long as its content falls within the above range, a favorable sensitivity and a high storage stability can be obtained.

From the viewpoint of the onboard development of an unexposed part in the image recording layer, it is preferable that the binder polymer is highly soluble or dispersible in an ink and/or a fountain solution.

To elevate the solubility or dispersibility in an ink, it is preferable that the binder polymer has a lipophilicnature. To elevate the solubility or dispersibility in a fountain solution, on the other hand, it is preferable that the binder polymer has a hydrophilic nature. It is, therefore, also effective in the invention to use a lipophilic binder polymer together with a hydrophilic binder polymer.

As the hydrophilic binder polymer, use can be appropriately made of those having a hydrophilic group, for example, a hydroxy group, a carboxy group, a carboxylate group, a hydroxyethyl group, a polyoxyethyl group, a hydroxypropyl group, a polyoxypropyl group, an amino group, an aminoethyl group, an aminopropyl group, an ammonium group, an amido group, a carboxymethyl group, a sulfonate group or a phosphate group.

Specific examples thereof include gum arabic, casein, gelatin, starch derivatives, carboxymethylcellulose and its sodium salt, cellulose acetate, sodium alginate, vinyl acetate-maleicacidcopolymers, styrene/maleicacidcopolymers, polyacrylic acids and salts thereof, polymethacrylic acids and salts thereof, hydroxyethyl methacrylate homopolymer and copolymers, hydroxyethyl acrylate homopolymer and copolymers, hydroxypropyl methacrylate homopolymer and copolymers, hydroxypropyl acrylate homopolymer and copolymers, hydroxybutyl methacrylate homopolymer and copolymers, hydroxybutyl acrylate homopolymer and copolymers, polyethylene glycols, hydroxypropylene polymers, polyvinyl alcohols, hydrolyzed polyvinyl acetate, polyvinyl formal, polyvinyl butyral and polyvinyl pyrrolidone each having a degree of hydrolysis of 60% by mass or more, preferably 80% by mass or more, acrylamide homopolymer and copolymers, methacrylamide homopolymer and copolymers, N-methylol acrylamide homopolymer and copolymers, polyvinylpyrrolidone, alcohol-soluble nylon, 2,2-bis-(4-hydroxyphenyl)-propane-epichlorohydrin polyether and so on.

The weight-average molecular weight of the binder polymer is preferably 5,000 or more, still preferably from 10,000 to 300,000. Its number-average molecular weight is preferably 1,000 or more and still preferably from 2,000 to 2,500,000. The polydispersion degree (weight-average molecular weight/number-average molecular weight) is preferably 1 or more, still preferably from 1.1 to 10.

Although the above-described binder polymer may be a random polymer, a block polymer, a graft polymer or the like, a random polymer is preferred.

Such a binder polymer can be synthesized by conventionally known methods. A binder polymer having a crosslinkable group in its side chain can be easily synthesized by radical polymerization or a polymer reaction.

The binder polymer to be used in the invention may be a single compound. Alternatively, use may be made of a mixture thereof.

The content of the binder polymer in the image recording layer preferably ranges from 10 to 90% by mass, still preferably from 20 to 80% by mass, based on the total solid matters in the image recording layer. So long as its content falls within this range, a favorable image strength and favorable image forming properties can be obtained.

It is also preferred that the polymerizable compound and the binder polymer are employed at a ratio by mass of 1/9 to 7/3.

[(F) Surfactant]

In the image recording layer according to the invention, use may be made of a surfactant in order to improve the coated face properties upon drying (in particular, quick drying), prevent phase separation and promote onboard development at the initiation of printing. As the surfactant, nonionic surfactants, anionic surfactants, cationic surfactants, amphoteric surfactants and surfactants containing fluorine may be cited. Either a single surfactant or a combination of two or more may be used.

As the nonionic surfactant to be used in the invention, use may be made of publicly known ones without particular restriction. Examples thereof include polyoxyethylene alkyl ethers, polyoxyethylene alkylphenyl ethers, polyoxyethylene polystyrylphenyl ethers, polyoxyethylene polyoxypropylene alkyl ethers, glyerol fatty acid partial esters, sorbitan fatty acidpartial esters, pentaerythritol fattyacidpartial esters, propylene glycol monofatty acid partial esters, sucrose fatty acid partial esters, polyoxyethylene sorbitan fatty acid partial esters, polyoxyethylene sorbitol fatty acid partial esters, polyethylene glycol fatty acid esters, polyglycerol fatty acid partial esters, polyoxyethylenated castor oils, polyoxyethylene glycerol fatty acid partial esters, fatty acid diethanolamides, N,N-bis-2-hydroxyalkylamines, polyoxyethylene alkylamines, triethanolamine fatty acid esters, trialkylamine oxides, polyethylene glycol, polyethylene glycol/polypropylene copolymer and so on.

As the anionic surfactant to be used in the invention, use may be made of publicly known ones without particular restriction. Examples thereof include fatty acid salts, abietic acid salts, hydroxyalkanesulfonic acid salts, alkanesulfonic acid salts, dialkylsulfosuccinic acid ester salts, linear alkylbenzenesulfonic acid salts, branched alkylbenzenesulfonic acid salts, alkylnaphthalenesulfonic acid salts, alkylphenoxypolyoxyethylene propylsulfonic acid salts, polyoxyethylene alkylsulfophenyl ether salts, N-methyl-N-oleyltaurine sodium salt, N-alkylsulfossucinic acid monoamide disodium salts, petroleum sulfonic acid salts, sulfatedbeef tallow, fatty acid alkyl ester sulfuric acid ester salts, alkylsulfuric acid ester salts, polyoxyethyelne alkyl ether sulfuric acid ester salts, fatty acid monoglceride sulfuric acid ester salts, polyoxyethylene alkylphenyl ether sulfuric acid ester salts, polyoxyethylene styrylphenyl ether sulfuric acid ester salts, alkylphosphoric acid ester salts, polyoxyethylene alkyl ether phosphoric acid ester salts, polyoxyethylene alkylphenyl ether phosphoric acid ester salts, partly saponified styrene/maleic anhydride copolymers, partly saponified olefin/maleic anhydride copolymers and naphthalenesulfonic acid salt/formalin condensates.

As the cationic surfactant to be used in the invention, use may be made of publicly known ones without particular restriction. Examples thereof include alkylamine salts, quaternary ammonium salts, polyoxyethylene alkylamine salts and polyethylene polyamine derivatives.

As the amphoteric surfactant to be used in the invention, use may be made of publicly known ones without particular restriction. Examples thereof include carboxybetaines, aminocarboxylic acids, sulfobetaines, aminosulfuric acid esters and imidazolines.

In the above-described surfactants, the term “polyoxyethylene” is also applicable to other “polyoxyalkylenes” such as polyoxymethylene, polyoxypropylene and polyoxybutylene. Such surfactants are also usable in the invention.

As a still preferable example of the surfactant, a fluorine-containing surfactant having a perfluoroalkyl group in its molecule can be cited. Examples of such a surfactant include anionic surfactants such as perfluoroalkylcarboxylic acid salts, perfluoroalkylsulfonic acid salts, perfluoroalkylphoshporic esters; amphoteric surfactants such as perfluoroalkylbetaines; cationic surfactants such as perfluoroalkyltrimethylammonium salts; and nonionic surfactants such as perfluoroalkylamine oxides, perfluoroalkyl ethylene oxide adducts, oligomers having a perfluoroalkyl group and a hydrophilic group, oligomers having a perfluoroalkyl group and a lipophilic group, oligomers having a perfluoroalkyl group, a hydrophilic group and a lipophilic group, and urethanes having a perfluoroalkyl group and a lipophilic group. Also, fluorine-containing surfactants described in JP-A-62-170950, JP-A-62-226143 and JP-A-60-168144 can be also cited as preferable ones.

Either one of these surfactants or a combination of two or more thereof may be used.

It is preferable that the image recording layer contains from 0.001 to 10% by mass, still preferably from 0.01 to 7% by mass, of the surfactant.

[Other Additives]

The image recording layer according to the invention may further contain additives other than the above-described components, for example, a coloring agent, a printout agent, a polymerization inhibitor, a higher fatty acid derivative, aplasticizer, inorganic fine particles, a low-molecular weight hydrophilic compound and so on.

<Coloring Agent>

The image recording layer according to the invention may contain a dye showing large absorption in the visible light region as a coloring agent. Particular examples thereof include Oil Yellow #101, Oil Yellow #103, Oil Pink #312, Oil Green BG, Oil Blue BOS, Oil Blue #603, Oil Black BY, Oil Black BS and Oil Black T-505 (manufactured by Orient Chemical Industries, Ltd.), Victoria Pure Blue, Crystal Violet (CI42555), Methyl Violet (CI42535), Ethyl Violet, Rhodamine B (CI45170B), Malachite Green (CI42000), Methylene Blue (CI52015), etc. and dyes described in JP-A-62-293247. Moreover, use may be appropriatelymade of pigments such as phthalocyanine pigments, azo pigments, carbon black and titanium oxide.

It is preferable to add such a coloring agent after forming an image, since an image part can be easily distinguished from a nonimage part. The addition level thereof ranges from 0.01 to 10% by mass in the image recording layer.

<Printout Agent>

To the image recording layer according to the invention, a compound undergoing a color change by the action of an acid or a radical can be added to form a printout image. As such a compound, it is effective to employ various colorants of, for example, diphenylmethane, triphenylmethane, thiazine, oxazine, xanthene, anthraquinone, iminoquinone, azo and azomethine types.

Specific examples thereof include Brilliant Green, Ethyl Violet, Methyl Green, Crystal Violet, Basic Fucsine, Methyl Violet 2B, Quinaldine Red, Rose Bengal, Metanyl Yellow, thymol sulfophthaleine, Xylenol Blue, Methyl Orange, Paramethyl Red, Congo Red, Benzopurpurine 4B, α-Naphthyl Red, Nile Blue 2B, Nile Blue A, Methyl Violet, Malachite Green, Parafucsine, Victoria Pure Blue BOH (manufactured by Hodogaya Chemical Co., Ltd.) Oil Blue #603 (manufactured by orient Chemical Industries, Ltd.), Oil Oink #312 (manufactured by orient Chemical Industries, Ltd.), Oil Red 5B (manufactured by Orient Chemical Industries, Ltd.), Oil Scarlet #308 (manufactured by Orient Chemical Industries, Ltd.), Oil Red OG (manufactured by Orient Chemical Industries, Ltd.), Oil Red RR (manufactured by Orient Chemical Industries, Ltd.), Oil Green #502 (manufactured by Orient Chemical Industries, Ltd.), Spiron Red BEH Special (manufactured by Hodogaya Chemical Co., Ltd.), m-Cresol Purple, Cresol Red, Rhodamine B, Rhodamine 6G, Sulforhodamine B, Aulamine, 4-p-diethylaminophenyliminonaphthoquine, 2-carboxyanilino-4-p-diethylaminophenyliminonaphthoquine, 2-carboxystearylamino-4-p-N,N-bis(hydroxyethyl)amino-pheny liminonaphthoquine, pyrazolone dues such as 1-phenyl-3-methyl-4-p-diethylaminophenylimino-5-pyrazolone and 1-β-naphthyl-4-p-diethylaminophenylimino-5-pyrazolone, and leuco dyes such as p′,p″-hexamethyltriaminotriphenylmethane (Leucocrystal Violet) and Pergascript Blue SRB (manufactured by Ciba-Geigy).

In addition to the above-described dyes, leuco dyes which have been known as materials for heat-sensitive paper and pressure-sensitive paper are also appropriately usable. Specific examples thereof include Crystal Violet Lactone, Malachite Green Lactone, Benzoyl Leucomethylene Blue,
2-(—N-phenyl-N-methylamino)-6-(N-p-tolyl-N-ethyl)amino-fluorane, 2-anilino-3-methyl-6-(N-ethyl-p-toluidino)fluorane,
3,6-dimethoxyfluorane,
3-(N,N-diethylamino)-5-methyl-7-(N,N-dibenzylamino)-fluorane,
3-(N-cyclohexyl-N-methylamino)-6-methyl-7-anilinofluorane,
3-(N,N-diethylamino)-6-methyl-7-xylidinofluorane,
3-(N,N-diethylamino)-6-metmhyl-7-chlorofluorane,
3-(N,N-diethylamino)-6-methoxy-7-aminofluorane,
3-(N,N-diethylamino)-7-(4-chloroanilino)fluorane,
3-(N,N-diethylamino)-7-chlorofluorane,
3-(N,N-diethylamino)-7-benzylaminofluorane,
3-(N,N-diethylamino)-7,8-benzofluorane,
3-(N,N-dibutylamino)-6-methyl-7-anilinofluorane,
3-(N,N-dibutylamino)-6-methyl-7-xylidinofluorane,
3-piperidino-6-methyl-7-anilinofluorane,
3-pyrolidino-6-methyl-7-anilinofluorane,
3,3-bis(1-ethyl-2-methylindol-3-yl)phthalide,
3,3-bis(1-n-butyl-2-methylindol-3-yl)phthalide,
3,3-bis(p-dimethylaminophenyl)-6-dimethylaminophthalide,
3-(4-diethylamino-2-ethoxyphenyl)-3-(1-ethyl-2-methylindol-3-yl)-4-phthalide,
3-(4-diethylaminophenyl)-3-(1-ethyl-2-methylindol-3-yl)phthalide and so on.

It is preferable to add such a dye undergoing a color change by the action of an acid or aradical to the image recording layer at a ratio of from 0.01 to 10% by mass.

<Heat Polymerization Inhibitor>

It is preferable to add a small amount of a heat polymerization inhibitor to the image recording layer according to the invention in order to prevent the polymerizable compound (C) from unnecessary heat polymerization during the production or storage of the image recording layer.

Preferable examples of the heat polymerization inhibitor include hydroquinone, p-methoxyphenol, di-t-butyl-p-cresol, pyrogallol, t-butyl catechol, benzoquinone, 4,4′-thiobis(3-methyl-6-t-butylphenol), 2,2′-methylenebis(4-methyl-6-t-butylphenol) and N-nitroso-N-phenylhydroxylamine aluminum salt.

It is preferable that the image recording layer contains the heat polymerization initiator in an amount of from about 0.01 to about 5% by mass.

<Higher Fatty Acid Derivative, etc.>

To prevent polymerization inhibition by oxygen, the image recording layer according to the invention may contain a higher fatty acid derivative such as behenic acid or behenic acid amide. The higher fatty acid derivative may be localized on the surface of the image recording layer in the course of drying following coating. The content of the higher fatty acid derivative preferably ranges from about 0.1 to about 10% by mass based on the total solid matters in the image recording layer.

<Plasticizer>

To improve the onboard development, the image recording layer according to the invention may contain a plasticizer. Preferable examples of the plasticizer include phthalic acid esters such as dimethyl phthalate, diethyl phthalate, dibutyl phthalate, diisobutyl phthalate, dioctyl phthalate, octylcapryl phthalte, dicyclohexyl phthalate, ditridecyl phthalate, butylbenzyl phthalate, diisodecyl phthalate and diallyl phthalate; glycol esters such as dimethyl glycol phthalate, ethylphthalyethyl glycolate, methylphthalylethyl glycolate, butylphthalylbutyl glycolate and triethylene glycol dicaprylic acid ester; phosphoric acid esters such as tricresyl phosphate and triphenyl phosphate; aliphatic dibasic acid esters such as diisobutyl adipate, dioctyl adipate, dimethyl sebacate, dibutyl sebacate, dioctyl azelate and dibutyl maleate; polyglycidyl methacrylate, triethyl citrate, glycerol triacetyl ester and butyl laurate.

<Inorganic Fine Particle>

To enhance interface adhesion by surface-roughening, elevate hardened film strength in an image part and improve onboard development in a nonimage part, the image recording layer according to the invention may contain inorganic fine particles.

Preferable examples of the inorganic fine particles include thosemade of silica, alumina, magnesiumoxide, titanium oxide, magnesium carbonate, calcium alginate or a mixture thereof.

The average particle diameter of the inorganic fine particles ranges preferably from 5 nm to 10 μm, still preferably from 0.5 μm to 3 μm. So long a the particle diameter falls within the above range, the inorganic fine particles are stably dispersed in the image recording layer so that the film strength of the image recording layer can be sustained at a sufficient level and a highly hydrophilic nonimage part scarcely suffering from staining during printing can be obtained.

The inorganic fine particles as described above can be easily obtained as a marketed product such as a colloidal silica dispersion.

It is preferable that the content of the inorganic fine particles is 20% by mass or less, still preferably 10% by mass or less based on the total solid matters in the image recording layer.

<Low-Molecular Weight Hydrophilic Compound>

To improve the onboard development, the image recording layer according to the invention may contain a low-molecular weight hydrophilic compound. Examples of the low-molecular weight hydrophilic compound include water-soluble organic compounds, e.g., glycols such as ethylene glycol, diethylene glycol, triethylene glycol, propylene glycol, dipropylene glycol and tripropylene glycol, ethers or esters thereof, polyhydroxy compounds such as glycerol and pentaerythritol, organic amines such as triethanolamine, diethanolamine and monoethanolamine and salts thereof, organic sulfonic acids such as toluenesulfonic acid and benzenesulfonic acid and salts thereof, organic phosphonic acids such as phenylphosphonic acid and salts thereof and organic carboxylic acids such as tartaric acid, oxalicacid, citricacid,malicacid, lacticacid, gluconic acid and amino acids and salts thereof.

[Formation of Image Recording Layer]

As a method of adding the above-described image recording layer-constituting components to the image recording layer in the invention, use can be made of several embodiments. In an embodiment, a molecule-dispersion type image recording layer is obtained by dissolving the components in an appropriate solvent and coating, as described in, for example, JP-A-2002-287334. In another embodiment, all or a part of the components are microcapsulated and contained in the image recording layer, i.e., a microcapsule type image recording layer as described in, for example, JP-A-2001-277740 and JP-A-2001-27742. The microcapsule type image recording layer may further contain component(s) other than the microcapsules. In a preferred embodiment, the microcapsule type image recording layer contains hydrophobic components in the microcapsules and hydrophilic components outside the microcapsules. To obtain further improved onboard development, it is advantageous to employ such a microcapsule type image recording layer as the image recording layer.

To microcapsulate the image recording layer-constituting components as described above, a publicly known method can be used. To produce microcapsules, for example, use can be made of coacervating methods as described in U.S. Pat. No. 2,800,457 and U.S. Pat. No. 2,800,458, interfacial polymerization methods as described in U.S. Pat. No. 3,287,154, JP-B-38-19574 and JP-B-42-446, polymer sedimentation methods as described in U.S. Pat. No. 3,418,250 and U.S. Pat. No. 3,660,304, a method with the use of an isocyanate polyol wall material as described in U.S. Pat. No. 3,796,669, a method with the use of an isocyanate wall material as described in U.S. Pat. No. 3,914,511, methods with the use of urea/formaldehyde or urea/formaldehyde/resorcinol wall-forming materials as described in U.S. Pat. No. 4,001,140, U.S. Pat. No. 4,087,376 and U.S. Pat. No. 4,089,802, methods with the use of wall materials such as a melamine/formaldehyde resin and hydroxycellulose as described in U.S. Pat. No. 4,025,445, in situ methods using a monomer as described in JP-B-36-9163 and JP-B-51-9079, spray drying methods as described in British Patent 930422 and U.S. Pat. No. 3,111,407, and electrolytic dispersion cooling methods as described in British Patent 952807 and British Patent 967074, though the invention is not restricted thereto.

In the invention, it is preferable to use a microcapsule wall which has a three-dimensional cross linkage and is swellable in a solvent. From this viewpoint, it is preferable that the microcapsule wall is made of polyurea, polyurethane, polyester, polycarbonate, polyamide or a mixture thereof. Among all, polyurea and polyurethane are particularly preferable. Moreover, a compound having a crosslinkable functional group such as an ethylenic unsaturated bond, which can be introduced into the above-described binder polymer, may be introduced into the microcapsule wall.

The particle diameter of the microcapsules as described above preferably ranges from 0.01 to 3.0 μm, still preferably from 0.05 to 2.0 μm and particularly preferably from 0.10 to 1.0 μm. So long as the particle diameter falls within this range, favorable resolution and a high stability with the passage of time can be established.

The image recording layer according to the invention may be formed y by dissolving the components required in the image recording layer as described above in a solvent and coating the thus prepared coating solution. Examples of the solvent to be used herein include ethylene dichloride, cyclohexanone, methyl ethyl ketone, methanol, ethanol, propanol, ethylene glycol monomethyl ether, 1-methoxy-2-propanol, 2-methoxyethyl acetate, 1-methoxy-2-propyl acetate, dimethoxyethane, methyl lactate, ethyl lactate, N,N-dimethylacetamide, N,N-dimethylformamide, tetramethyl urea, N-methyl pyrrolidone, dimethyl sulfoxide, sulfolane, γ-butyrolactone, toluene and water, though the invention is not restricted thereto. Either one of these solvents or a mixture thereof may be used. The concentration of the solid matters in the coating solution appropriately ranges from 1 to 50% by mass.

It is also possible to form the image recording layer according to the invention by dispersing/dissolving the same or different components as described above in the same or different solvents to give a plural number of coating solutions and repeating the coating and drying steps twice or more.

It is generally preferable that the coating dose (solid content) of the image recording layer on the support after drying ranges from about 0.3 to about 3.0 g/m². So long as the coating dose falls within this range, a favorable sensitivity and favorable film properties of the image recording layer can be obtained.

Coating may be performed by various methods such as bar coater coating, spin coating, spray coating, curtain coating, dip coating, air knife coating, blade coating and roll coating.

[Support]

The support to be used in the lithographic printing plate precursor according to the invention is not particularly restricted, so long as it is a sheet type material having a high dimensional stability. Examples thereof include papers, papers having plastics (for example, polyethylene, polypropylene, polystyrene, etc.) laminated thereon, metal sheets (for example, aluminum, zinc, copper, etc.), plastic films (for example, cellulose diacetate, cellulose triacetate, cellulose propionate, cellulose butyrate, cellulose acetate butyrate, cellulose nitrate, polyethylene terephthalate, polyethylene, polystyrene, polypropylene, polycarbonate, polyvinyl acetal, etc.) and papers and plastic films having the above-described meals laminated thereon. Among all, a polyester film and an aluminum sheet are preferable as the support. In particular, an aluminum sheet is preferred because of being excellent in dimensional stability and relatively less expensive.

Appropriate examples of the aluminum sheets are pure aluminum sheets and alloy sheets comprising aluminum as the main component together with a different element in a trace amount. Moreover, it is also possible to use a plastic film having aluminum laminated or evaporated thereon. Examples of the different element contained in the aluminum alloys include silicon, iron, manganese, copper, magnesium, chromium, zinc, bismuth, nickel, titanium and so on. It is preferable that the content of such a different element in an alloy is 10% by weight at the largest. Although pure aluminum is appropriate as the aluminum sheet to be used in the invention, completely pure aluminum can be hardly produced from the viewpoint of refining techniques. Thus, use may be made of one containing a small amount of a different element. That is to say, the aluminum sheet to be applied in the invention is not restricted in its composition but aluminum sheets having been publicly known and used can be appropriately employed.

The thickness of the support ranges preferably from about 0.1 to 0.6 mm, still preferably from 0.15 to 0.4 mm and particularly preferably from 0.2 to 0.3 mm.

Before using the aluminum sheet, it is preferable to carry out a surface treatment such as roughening or anodic oxidation. Owing to the surface treatment, the hydrophilic nature can be improved and the adhesion of the image recording layer to the support can be ensured. Before roughening the surface of the aluminum sheet, a degreasing treatment is carried out to remove a rolling-mill oil from the surface with the use of, for example, a surfactant, an organic solvent or an aqueous alkali solution.

The treatment for roughening the aluminum sheet surface can be carried out by various methods, for example, a mechanical roughening method, an electrochemical surface roughening method (a method of roughening the surface by electrochemically solubilizing the surface) and a chemical surface roughening method (a method of chemically solubilizing the surface selectively).

As the mechanical roughening method, use can be made of publicly known methods such as the ball grinding method, the brush grinding method, the blast grinding method and the buff grinding method.

As the electrochemical surface roughening method, use may be made of a roughening method which is carried out in a hydrochloric acid or nitric acid electrolytic solution under an alternating current or a direct current. It is also possible to use an acid mixture as disclosed in JP-A-54-63902.

If desired, the thus surface-roughened aluminum sheet may be further subjected to alkali etching with the use of an aqueous solution of, for example, potassium hydroxide or sodium hydroxide and neutralization followed by anodic oxidation to improve the abrasion resistance of the surface.

As the electrolyte to be employed in the anodic oxidation of the aluminum sheet, use may be made of various electrolytes forming a porous oxidation film. In general, sulfuric acid, phosphoric acid, oxalic acid, chromic acid or a mixture of these acids is used. The concentration of such an electrolyte may be appropriately determined depending on the type of the electrolyte.

The treatment conditions for the anodic oxidation cannot be determined in general since they vary depending on the electrolyte employed. In general, it is appropriate that the concentration of the electrolyte solution ranges from 1 to 80% by mass, the solution temperature ranges from 5 to 70° C., the current density ranges from 5 to 60 A/dm², the voltage ranges from 1 to 100 V and the electrolysis time ranges from 10 sec to 5 min. It is appropriate that the amount of the anodic oxidation film is 1.0 to 5.0 g/m², still preferably from 1.5 to 4.0 g/m². Within this range, favorable scuff resistance can be established.

After the above-described anodic oxidation treatment, the surface of the aluminum sheet is subjected to hydrophilization by using a conventionally known method. The hydrophilization may be carried out by the method with the use of an alkali metal silicate as disclosed by U.S. Pat. No. 2,714,066, U.S. Pat. No. 3,181,461, U.S. Pat. No. 3,280,734 and U.S. Pat. No. 3,902,734. In this method, the support is soaked in an aqueous sodium silicate solution or electrolyzed. Alternatively, use may be made of a method of treating with potassium fluorozirconate as disclosed by JP-B-36-22063 or a method of treating with polyvinylphosphonic acid as disclosed by U.S. Pat. No. 3,276,868, U.S. Pat. No. 4,153,461 and U.S. Pat. No. 4,689,272.

The centerline average roughness of the support ranges preferably from 0.10 to 1.2 μm. Within this range, a favorable adhesion to the image recording layer, a favorable scuff resistance and an excellent stain resistance can be established.

The color density of the support expressed in reflective density ranges preferably from 0.15 to 0.65. Within this range, favorable image forming properties and favorable post-development plate characteristics can be obtained by the prevention of halation at image exposure.

(Backcoat Layer)

After surface-treating or forming an undercoat layer, a backcoat may be formed on the back face of the support, if necessary.

As the backcoat, it is preferable to use coating layers made of an organic polymer compound described in JP-A-5-45885 or a metal oxide obtained by hydrolyzing and polycondensing an organic or inorganic metal compound described in JP-A-6-35174. Among these coating layers, a coating layer made of metal oxide obtained from a silicon alkoxy compound such as Si(OCH₃)₄, Si(OC₂H₅)₄, SI(OC₃H₇)₄ or Si(OC₄H₉)₄ is particularly preferable, since such a material is easily available at a low cost.

(Undercoat Layer)

If desired, the lithographic printing plate precursor according to the invention to be used in the lithographic printing method according to the invention may further have an undercoat layer between the image recording layer and the support. It is advantageous to form the undercoat layer, since it serves as a heat-insulating layer and thus heat generated by the infrared laser irradiation can be efficiently utilized without diffusion toward the support, thereby achieving a high sensitivity. In an unexposed part, the undercoat layer facilitates the separation of the image recording layer from the support and thus improved the onboard development.

As the undercoat layer, use can be made of a silane coupling agent having an ethylenic double bond reactive group capable of undergoing addition polymerization and a phosphorus compound having an ethyleneic double bond reactive group can be appropriately cited.

The coating dose of the undercoat layer ranges preferably from 0.1 to 100 mg/m² (in terms of solids), still preferably from 3 to 30 mg/m².

(Protective Layer)

If necessary, the lithographic printing plate precursor according to the invention to be used in the lithographic printing method according to the invention may further have a protective layer on the above-described image recording layer in order to prevent scuffs in the image recording layer, block oxygen and prevent ablation upon high-illumination laser exposure.

In the invention, exposure is usually performed in the atmosphere. The protective layer prevents the image recording layer from the invasion of low-molecular weight compounds such as oxygen and basic substances which occur in the atmosphere and inhibit the image formation reaction proceeding due to the exposure, thereby enables the exposure in the atmosphere. Accordingly, it is required that such a protective layer has a low permeability for the low-molecular weight compounds such as oxygen but a high permeability for light to be used in the exposure, is excellent in the adhesion to the image recording layer and can be easily removed in the development step following the exposure. Concerning such a protective layer, devices have been made as reported in detail in U.S. Pat. No. 3,458,311 and JP-A-55-49729.

As materials usable in the protective layer, it is favorable to employ, for example, water-soluble polymer compounds having relatively high crystallinity. More specifically speaking, there have been known water-soluble polymers such as polyvinyl alcohol, polyvinylpyrrolidone, acidic celluloses, gelatin, gum arabic and polyacrylic acid. Among these polymers, the most desirable results in fundamental properties (oxygen-blocking, removal in development, etc.) can be obtained by using polyvinyl alcohol as the main component. The polyvinyl alcohol to be used in the protective layer may be partly substituted by an ester, an ether or acetal, so long as it carries unsubstituted vinyl alcohol units for achieving the required oxygen-blocking properties and solubility in water. Similarly, it may partly have another comonomer.

Particular examples of the polyvinyl alcohol include those which are hydrolyzed to an extent of 71 to 100% and have a molecular weight of from 300 to 2400. More specifically speaking, use can be made of PVA-105, PVA-110, PVA-117, PVA-117H, PVA-120, PVA-124, PVA-124H, PVA-CS, PVA-CST, PVA-HC, PVA-203, PVA-204, PVA-205, PVA-210, PVA-217, PVA-220, PVA-224, PVA-217EE, PVA-217E, PVA-220E, PVA-224E, PVA-405, PVA-420, PVA-613, L-8, etc. each manufactured by KURARAY.

The components (the type of PVA, use of additive(s)), coating dose, etc. of the protective layer are selected by taking the oxygen-blocking properties and development removal as well as fogging, adhesiveness and scuff resistance into consideration. In general, a higher hydrolysis ratio of the employed PVA (i.e., the higher content of the unsubstituted vinyl alcohol units in the protective layer) brings about the higher oxygen-blocking properties, which is advantageous from the viewpoint of sensitivity. To prevent the occurrence of an unnecessary polymerization during production or storage and unnecessary fogging or line thickening during exposure of the image, it is preferred to control the oxygen permeability. Thus, it is preferable that the oxygen permeability (A) at 25° C. under 1 atm is 0.2≦A≦20 (cc/m²day).

The molecular weight of the (co) polymer such as polyvinyl alcohol (PVA) as described above ranges preferably from 2,000 to 10,000,000, appropriately form 20,000 to 3,000,000.

As additional components of the protective layer, use can be made of several % by mass (based on the (co)polymer) of glycerol, dipropylene glycol, etc. to thereby impart flexibility. It is also possible to add several % by mass (based on the (co)polymer) of an anionic surfactant such as a sodium alkylsulfate or a sodium alkylsulfonate; an amphoteric surfactant such as an alkylaminocarboxylic acid salt or an alkylaminodicarboxylic acid salt; or a nonionic surfactant such as a polyoxyethylene alkyl phenyl ether.

The film thickness of the protective layer ranges appropriately from 0.1 to 5 μm, still appropriately from 0.2 to 2 μm.

Adhesion, scuff resistance, etc. of an image part in the protective layer are highly important in handling the lithographic printing plate precursor. That is to say, when a hydrophilic protective layer made of a water-soluble polymer is laminated upon a lipophilic image recording layer, the insufficient adhesive force frequently causes film separation and the separated part induces troubles such as film hardening failure due to the inhibition of the polymerization by oxygen.

To overcome this problem, various proposals have been made to improve the pressure-sensitive adhesion between the image recording layer and the protective layer. For example, JP-A-49-70702 and British Patent 1303578 report that a sufficient pressure-sensitive adhesion can be achieved by mixing a hydrophilic polymer mainly comprising polyvinyl alcohol with 20 to 60% by mass of an acrylic emulsion, a water-insoluble vinylpyrrolidone/vinyl acetate copolymer, etc. and laminating on the polymerization layer. Any of these publicly known techniques are applicable to the protective layer in the invention. Methods of coating the protective layer are described in, for example, U.S. Pat. No. 3,458,311 and JP-A-55-49729.

Further functions may be imparted to the protective layer. For example, addition of a coloring agent (e.g., a water-soluble dye) having an excellent permeability of infrared rays employed in the exposure and being capable of well absorbing rays of other wavelengths makes it possible to improve safe light applicability without lowering sensitivity.

(Lithographic Printing Method)

In the lithographic printing method according to the invention, the above-described lithographic printing plate precursor is exposed to infrared laser beams in an image pattern.

Although the infrared laser to be used in the invention is not particularly restricted, it is preferable to use a solid laser or a semiconductor laser radiating infrared rays of 760 nm to 1200 nm. The output of the infrared laser is preferably 100 mW or more. To shorten the exposure time, it is preferable to use a multibeam laser device.

It is preferable that the exposure time per pixel is not longer than 20 μsec. The irradiation energy preferably ranges from 10 to 300 mJ/cm².

In the lithographic printing method according to the invention, the lithographic printing plate precursor according to the invention is exposed to an infrared laser in an image pattern as described above. Next, an oily ink and an aqueous component are supplied and printing is carried out, without employing the development step.

After image-exposing the lithographic printing plate precursor with the infrared laser, an oily ink and an aqueous component are supplied and printing is carried out, without employing the development step such as the wet development treatment. In the exposed part of the image recording layer, the image recording layer hardened by the exposure provides an oily ink-receiving part having a lipophilic surface. In the unexposed part, on the other hand, the unhardened image recording layer is dissolved or dispersed in the aqueous component and/or the oily ink supplied thereto and removed. Thus, the hydrophilic surface is exposed in this part.

As a result, the aqueous component adheres to the hydrophilic surface thus exposed, while the oily ink adheres to the image recording layer in the exposed area, thereby initiating printing. Either the oily ink or the aqueous component may be first supplied to the plate, it is preferred to supply the oily ink first so as to prevent the unexposed part of the image recording layer from staining with the aqueous component. As the aqueous component and the oily ink, use can be made of a fountain solution and an oily ink commonly employed in lithography.

The lithographic printing plate precursor is thus onboard developed on an offset printer and employed as such in printing a large number of sheets.

### EXAMPLES

Now, the invention will be described in greater detail by reference to the following EXAMPLES. However, it is to be understood that the invention is not restricted thereto.

1. Construction of Lithographic Printing Plate Precursor

(1) Formation of Support

<Aluminum Sheet>

A JIS A1050 alloy melt containing 99.5% or more of Al together with 0.30% of Fe, 0.10% of Si, 0.02% of Ti and 0.013% of Cu (the balance being unavoidable impurities) was subjected to a cleaning treatment and then casted. The cleaning was carried out by degassing so as to eliminate unnecessary gases (hydrogen gas, etc.) in the melt and then treated with a ceramic tube filter. For the casting, the DC casting method was employed. The solidified ingot of 500 mm in plate thickness was faced to 10 mm from the surface and homogenized at 550° C. for 10 hours to prevent intermetal compounds from enlargement. Next, it was hot-rolled at 400° C., annealed in a continuous annealing furnace at 500° C. for 60 seconds and then cold rolled to give an aluminum plate of 0.3 mm in thickness. To control the coarseness of the rolling mill, the center line average surface roughness Ra after cold milling was controlled to 0.2 μm. Next, it was treated with a tension leveler to improve planarity. Next, a surface treatment was performed to give a lithographic support.

To remove the rolling mill oil from the surface, the aluminum plate was degreased with a 10% aqueous solution of sodium aluminate at 50° C. for 30 seconds and neutralized with a 30% aqueous solution of sulfuric acid at 50° C. for 30 seconds followed by desmutting.

Then the support was subjected to surface roughening to improve the adhesion between the support and the image recording layer and impart water retention properties to a non-image part. An aqueous solution containing 1% of nitric acid and 0.5% of aluminum nitrate was maintained at 45° C. and, while pouring an aluminum web into the aqueous solution, the plate was roughened by electrolysis by using an indirect feeder cell at a current density of 20 A/dm² and a sinusoidal alternate current (duty ratio 1:1) at an anodic electricity of 240 C/dm².

Next, it was etched with a 10% aqueous solution of sodium aluminate at 50° C. for 30 seconds and neutralized with a 30% aqueous solution of sulfuric acid at 50° C. for 30 seconds followed by desmutting.

To further improve abrasion resistance, chemical resistance and water retention, an oxidation film was formed on the support by anodic oxidation. Using a 20% aqueous solution of sulfuric acid at 35° C. as an electrolyte, the aluminum web was passed through the electrolyte and electrolyzed with direct current at 14 A/dm² from an indirect feeder cell, thereby giving an anodic oxidation film of 2.5 g/m².

To ensure the hydrophilic nature in the nonimage part, it was subjected to a silicate treatment with the use of a 1.5% by mass aqueous solution of sodium silicate No. 3 at 70° C. for 15 seconds. The coating dose of Si was 10 mg/m². After washing with water, a support was obtained. The centerline average roughness Ra of the thus obtained support was 0.25 pm.

(2) Formation of Image Recording Layer

### Examples 1 to 20, Comparative Example 1

A coating solution for the image recording layer of the following composition was prepared and coated to the support constructed above by using a bar. Then it was dried in an oven at 70° C. for 60 seconds. After drying, an image recording layer of the coating dose of 0.8 g/m² was formed to give a lithographic printing plate precursor.

Coating solution for image recording layer (1)

| | | |
|---|---|---|
| water | 100 | g |
| following microcapsule (1) (solid matters) | 5 | g |
| above-described polymerization initiator (OS-7) | 0.5 | g |
| following fluorine-containing surfactant (1) | 0.2 | g |

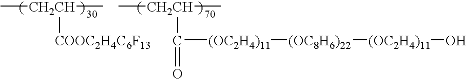

Fluorine-containing surfactant (1)

(Synthesis of Microcapsule (1))

As oily phase components, 10 g of trimethylol propane/xylene diisocyanate adduct (TAKENATE D-110N, manufactured by Mitsui Takeda Chemical), 3.15 g of pentaerythritol acrylate (SR444, manufactured by Nippon Kayaku Co., Ltd.), 0.35 g of the following infrared absorbing agent (1), 1 g of 3-(N,N-diethyamino)-6-methyl-7-anilinofluorane (ODB, manufactured by Yamamoto Kasei), a compound having carboxylate group as listed in the following Table 1 in the amount as specified in Table 1, and 0.1 g of PIONIN A-41C (manufactured by Takemoto Oil and Fat Co., Ltd.) were dissolved in 17 g of ethyl acetate. As an aqueous phase component, 40 g of a 4% by mass solution of PVA-205 was prepared. The oily phase components and the aqueous phase component were mixed together and emulsified in a homogenizer at 12,000 rpm for 10 minutes. The obtained emulsion was added to 25 g of distilled water, stirred at room temperature for 30 minutes and then stirred at 40° C. for 3 hours. The solid concentrations of the microcapsule solutions (16) to (20) thus obtained were adjusted to 20% by mass with distilled water. The average particle diameter was 0.3 μm in each case.

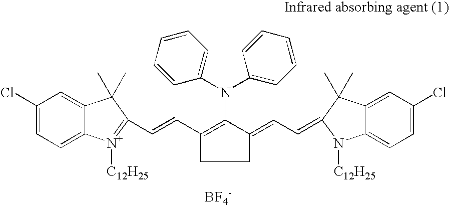

### Examples 21 to 40, Comparative Example 2

A coating solution for the image recording layer of the following composition was prepared and coated to the support constructed above by using a bar. Then it was dried in an oven at 100° C. for 60 seconds. After drying, an image recording layer of the coating dose of 1.0 g/M² was formed to give a lithographic printing plate precursor.

Coating solution for image recording layer (2)

| | | |
|---|---|---|
| following infrared absorbing agent (2) | 0.05 | g |
| above-described polymerization initiator (OS-7) | 0.2 | g |
| following binder polymer (1) (average Mw: 80,000) | 0.5 | g |
| polymerizable compound | 1.0 | g |
| (isocyanuric acid EO-modified triacrylate) | | |
| (NK Ester M-315 manufactured by Shin Nakamura Kogyo) | | |
| carboxylate-containing compound of Table 2 | | |
| amount as specified in Table 2 | | |
| Victoria Pure Blue naphthalenesulfonate | 0.02 | g |
| above-described fluorine-containing surfactant (1) | 0.1 | g |
| methyl ethyl ketone | 18.0 | g |

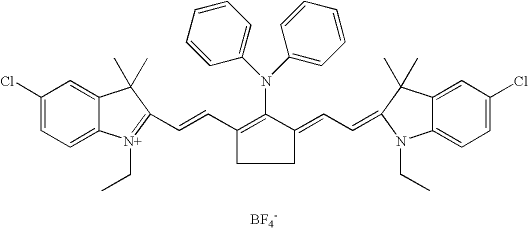

Infrared absorbing agent (2)

| | |
|---|---|
| 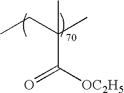 | 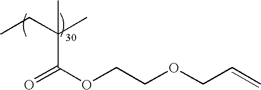 |

Binder polymer (1)

2. Exposure and Printing

The obtained negative lithographic printing plate precursors were each exposed by using a Trendsetter 3244VX (manufactured by Creo) equipped with a water-cooled 40W infrared semiconductor laser at an energy output of 9W, at outer drum rotation speed of 210 rpm, a plate energy of 100 mJ/cm² and at a resolution of 2400 dpi. The exposed image had a fine line chart. The printing plate precursor thus exposed was not subjected to a development treatment but loaded on the cylinder of a printer SOR-M (manufactured by Heiderberg). Using a fountain solution (EU-3, etching solution manufactured by Fuji Photo film and a black ink TRANS-G (N) (manufactured by Dainippon Ink and Chemicals), the fountain solution and the ink were supplied and 100 paper sheets were printed at a speed of 6,000 sheets per hour.

The number of the paper sheets having been printed until the onboard development of the unexposed part in the image recording layer was completed on the printer and the ink was not transferred to the printing paper any more was counted and referred to as the onboard development properties.

Stains in the nonimage part of a printed substrate after printing 100 sheets using a sensitive material with or without forced time course was evaluated with the naked eye. Tables 1 and 2 summarize the results.

TABLE 1

| | | | No. of | Stain in non image part | |
|---|---|---|---|---|---|
| | Compoun d | | onboard | No forced | 45° C. |
| | having car- | | developed | time | 75% RH 3 |
| Ex. | boxylate group | | sheets | course | days |
| Ex. 1 | AC-1 | 0.5 g | 20 | No stain | No stain |
| Ex. 2 | AC-2 | 0.5 g | 20 | No stain | No stain |
| Ex. 3 | AC-3 | 0.5 g | 20 | No stain | No stain |
| Ex. 4 | AC-4 | 0.5 g | 15 | No stain | No stain |
| Ex. 5 | AC-5 | 0.5 g | 15 | No stain | No stain |
| Ex. 6 | AC-6 | 0.5 g | 15 | No stain | No stain |
| Ex. 7 | AC-7 | 0.5 g | 15 | No stain | No stain |
| Ex. 8 | AC-8 | 0.5 g | 15 | No stain | No stain |
| Ex. 9 | AC-9 | 0.5 g | 15 | No stain | No stain |
| Ex. 10 | AC-10 | 0.5 g | 15 | No stain | No stain |
| Ex. 11 | AC-11 | 0.5 g | 15 | No stain | No stain |
| Ex. 12 | AC-12 | 0.5 g | 15 | No stain | No stain |
| Ex. 13 | AC-13 | 0.5 g | 15 | No stain | No stain |
| Ex. 14 | AC-14 | 0.5 g | 15 | No stain | No stain |
| Ex. 15 | AC-15 | 0.5 g | 15 | No stain | No stain |
| Ex. 16 | AC-16 | 0.5 g | 15 | No stain | No stain |
| Ex. 17 | AC-17 | 0.5 g | 15 | No stain | No stain |
| Ex. 18 | AC-18 | 0.5 g | 20 | No stain | No stain |
| Ex. 19 | AC-11 | 0.2 g | 20 | No stain | No stain |
| Ex. 20 | AC-11 | 0.8 g | 15 | No stain | No stain |

| | | | | |
|---|---|---|---|---|
| C. Ex. 1 | No | 40 | Stained | Stained |

TABLE 2

| | | | | No. of | Staininnonimagepart | |
|---|---|---|---|---|---|---|
| | | | | onboard | No forced | 45° C. |
| | Compound having | | | developed | time | 75% RH 3 |
| Ex. | carboxylate group | | | sheets | course | days |
| Ex.21 | AC-1 | 0.1 | g | 25 | No stain | No stain |
| Ex.22 | AC-2 | 0.1 | g | 25 | No stain | No stain |
| Ex.23 | AC-3 | 0.1 | g | 25 | No stain | No stain |
| Ex.24 | AC-4 | 0.1 | g | 20 | No stain | No stain |
| Ex.25 | AC-5 | 0.1 | g | 20 | No stain | No stain |
| Ex.26 | AC-6 | 0.1 | g | 20 | No stain | No stain |
| Ex.27 | AC-7 | 0.1 | g | 20 | No stain | No stain |
| Ex.28 | AC-8 | 0.1 | g | 20 | No stain | No stain |
| Ex.29 | AC-9 | 0.1 | g | 20 | No stain | No stain |
| Ex.30 | AC-10 | 0.1 | g | 20 | No stain | No stain |
| Ex.31 | AC-11 | 0.1 | g | 20 | No stain | No stain |
| Ex.32 | AC-12 | 0.1 | g | 20 | No stain | No stain |
| Ex.33 | AC-13 | 0.1 | g | 20 | No stain | No stain |
| Ex.34 | AC-14 | 0.1 | g | 20 | No stain | No stain |
| Ex.35 | AC-15 | 0.1 | g | 20 | No stain | No stain |
| Ex.36 | AC-16 | 0.1 | g | 20 | No stain | No stain |
| Ex.37 | AC-17 | 0.1 | g | 20 | No stain | No stain |
| Ex.38 | AC-18 | 0.05 | g | 25 | No stain | No stain |
| Ex.39 | AC-11 | 0.5 | g | 25 | No stain | No stain |
| Ex.40 | AC-11 | 0.8 | g | 15 | No stain | No stain |

| | | | | |
|---|---|---|---|---|
| C.Ex.2 | No | 45 | No stain | Stained |

Compound having carboxylate group

(AC-1)

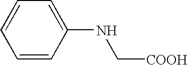

(AC-2)

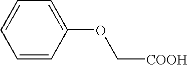

(AC-3)

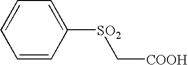

(AC-4)

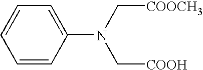

(AC-5)

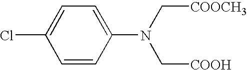

(AC-6)

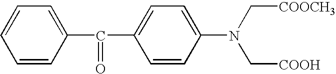

(AC-7)

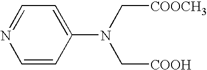

(AC-8)

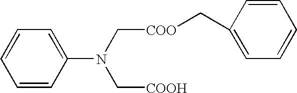

(AC-9)

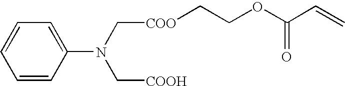

(AC-10)

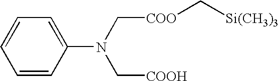

(AC-11)

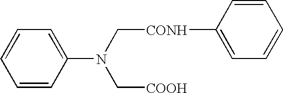

(AC-12)

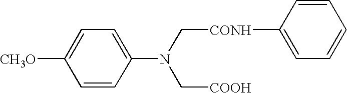

(AC-13)

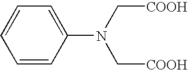

(AC-14)

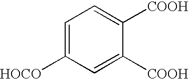

(AC-15)

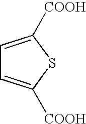

(AC-16)

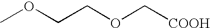

(AC-17)

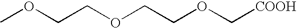

(AC-18)

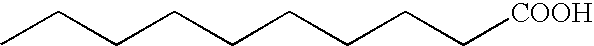

As the above Tables clearly show, the lithographic printing plate precursor according to the invention shows a small number of onboard development sheets and no worsening in the stain resistance in a nonimage part with the passage of time after development.

The invention is applicable to a lithographic printing plate precursor and a lithographic printing method using the same. More specifically, it relates to a lithographic printing plate precursor whereby a plate can be directly made by scanning with infrared lasers from digital signals of a computer or the like, i.e., so-called direct plate making, and a lithographic printing method wherein the above-described lithographic printing plate precursor is developed on a printer followed by printing.

This application is based on Japanese Patent application JP 2003-293814, filed Aug. 15, 2003, the entire content of which is hereby incorporated by reference, the same as if set forth at length.

1. A lithographic printing plate precursor comprising: a support; and an image recording layer containing (A) an infrared absorbing agent, (B) a polymerization initiator, (C) a polymerizable compound and (D) a compound having a carboxylate group and being removable with at least one of a printing ink and a fountain solution.

2. The lithographic printing plate precursor according to claim 1, wherein at least one of the components (A) to (D) is microcapsulated.

3. The lithographic printing plate precursor according to claim 1, wherein the compound (D) is a monocarboxylic acid compound represented by the following formula (I): 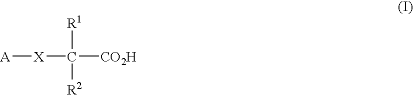
wherein A represents an aromatic group or a heterocyclic group;
R¹ and R² each independently represents a hydrogen atom or a monovalent substituent, and R¹ and R², one of R¹ and R² and X, one of R¹ and R² and A, or A and X may be bonded to each other to form a cyclic structure; and
X represents a divalent linking group selected from the group consisting of —O—, —S—, —SO₂—, —NH—, —N(R³)—, —CH₂—, —CH(R⁴)— and —C(R⁴)(R⁵)—, wherein R³, R⁴ and R⁵ each independently represents a hydrogen atom or a monovalent substituent.

4. The lithographic printing plate precursor according to claim 1, wherein the polymerization initiator (B) is an onium salt represented by one of the following formulae (B-I) to (B-III): 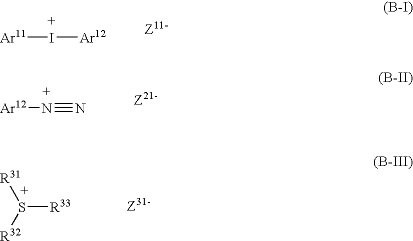
in which, in the formula (B-I), Ar¹¹ and Ar¹² each independently represents an optionally substituted aryl group having not more than 20 carbon atoms; and Z¹¹⁻ represents a counter ion selected from the group consisting of halogen ions, perchlorate ion, tetrafluoroborate ion, hexafluorophosphate ion, carboxylate ion and sulfonate ion;
in the formula (B-II), Ar²¹ represents an optionally substituted aryl group having not more than 20 carbon atoms; and Z²¹⁻ represents a counter ion selected from the group consisting of halogen ions, perchlorate ion, tetrafluoroborate ion, hexafluorophosphate ion, carboxylate ion and sulfonate ion; and
in the formula (B-III), R³¹, R³² and R³³ may be same or different and each represents an optionally substituted hydrocarbon group having not more than 20 carbon atoms; and Z^{31 -} represents a counter ion selected from the group consisting of halogen ions, perchlorate ion, tetrafluoroborate ion, hexafluorophosphate ion, carboxylate ion and sulfonate ion.

5. The lithographic printing plate precursor according to claim 1, wherein the polymerizable compound (C) is an addition-polymerizable compound having at least one ethylenically unsaturated double bond.

6. The lithographic printing plate precursor according to claim 1, wherein the image recording layer further contains (E) a binder polymer.

7. The lithographic printing plate precursor according to claim 1, wherein the image recording layer further contains (F) a surfactant.

8. A lithographic printing method comprising:
loading the lithographic printing plate precursor according to claim 1 on a printer;
exposing the lithographic printing plate precursor to infrared laser beams in an image pattern, before or after the loading; and
supplying an oily ink and an aqueous component to the lithographic printing plate precursor to thereby remove an infrared-unexposed part of the image recording layer of the lithographic printing plate precursor.
